(19) United States
(12) Patent Application Publication
(10) Pub. No.: US 2025/0267841 A1
(43) Pub. Date: Aug. 21, 2025

(54) SEMICONDUCTOR DEVICE

(71) Applicant: Samsung Electronics Co., Ltd., Suwon-si (KR)

(72) Inventor: Dongkyun Lim, Suwon-si (KR)

(21) Appl. No.: 19/026,782

(22) Filed: Jan. 17, 2025

(30) Foreign Application Priority Data
Feb. 15, 2024 (KR) 10-2024-0021559

(51) Int. Cl. H10B 12/00; G11C 11/4096

(52) U.S. Cl. CPC H10B 12/30; G11C 11/4096; H10B 12/03; H10B 12/50

(57) ABSTRACT

A semiconductor device includes active patterns stacked and spaced apart from each other in a vertical direction; and a capacitor connected to the active patterns. The capacitor includes first electrodes respectively connected to the active patterns and stacked and spaced apart from each other in the vertical direction; a second electrode penetrating through the first electrodes and extending in the vertical direction; a third electrode penetrating through the first electrodes and extending in the vertical direction, and spaced apart from the second electrode; first dielectric layers, each first dielectric layer being between a respective first electrode and the second electrode; and second dielectric layers, each second dielectric layer being between a respective first electrode and the third electrode.

### CROSS-REFERENCE TO RELATED APPLICATION

This application claims benefit of priority to Korean Patent Application No. 10-2024-0021559 filed on Feb. 15, 2024, in the Korean Intellectual Property Office, the disclosure of which is incorporated herein by reference in its entirety.

### BACKGROUND

The present disclosure relates to a semiconductor device including a data storage structure having three electrodes and a method of forming the same.

Research is being conducted to reduce the size of elements included in a semiconductor device and improve performance thereof. For example, in a DRAM, research is being conducted to reliably and stably form reduced-sized elements, but with the reduction in the size of the elements, dispersion characteristics of semiconductor devices are deteriorating.

### SUMMARY

An aspect of the present disclosure is to provide a semiconductor device that may increase a degree of integration and improve performance.

An aspect of the present disclosure is to provide a method of forming a semiconductor device.

A semiconductor device according to an example embodiment includes: active patterns stacked and spaced apart from each other in a vertical direction; and a capacitor connected to the active patterns, wherein the capacitor includes: first electrodes respectively connected to the active patterns and stacked and spaced apart from each other in the vertical direction; a second electrode penetrating through the first electrodes and extending in the vertical direction; a third electrode penetrating through the first electrodes and extending in the vertical direction, and spaced apart from the second electrode; first dielectric layers, each first dielectric layer being between a respective first electrode and the second electrode; and second dielectric layers, each second dielectric layer being between a respective first electrode and the third electrode.

A semiconductor device according to an example embodiment includes: a peripheral circuit region including a peripheral circuit; and a memory region on the peripheral circuit region and including cell blocks, wherein each of the cell blocks includes cell transistors and a data storage structure connected to first source/drain regions of the cell transistors, wherein the data storage structure of each of the cell blocks includes: first electrodes respectively connected to the first source/drain regions of the cell transistors, the first electrodes being stacked and spaced apart from each other in a vertical direction; a second electrode having a side surface facing the first electrodes; and a third electrode having a side surface facing the first electrodes and spaced apart from the second electrode, and wherein the peripheral circuit includes: a fixed voltage supply circuit configured to apply a fixed voltage to the second electrode; a write circuit configured to perform a write operation for storing “1” or “0” data in a unit memory cell of the cell blocks; and a variable voltage supply circuit configured to, during the write operation for storing data “1” in the unit memory cell, apply a positive voltage to the third electrode, and to, during the write operation for storing “0” data in the unit memory cell, apply a negative voltage to the third electrode.

A semiconductor device according to an example embodiment includes: active patterns stacked and spaced apart from each other in a vertical direction; and a data storage structure connected to the active patterns, wherein the data storage structure includes: first electrodes respectively connected to the active patterns, the first electrodes being stacked and spaced apart from each other in the vertical direction; a second electrode having a side surface facing the first electrodes; a third electrode having a side surface facing the first electrodes and spaced apart from the second electrode; first dielectric layers between respective first electrodes and the second electrode; and second dielectric layers between respective first electrodes and the third electrode.

According to example embodiments, a capacitor structure including three electrodes and capable of storing information may be provided. Among the three electrodes, first electrodes may be respectively connected to first source/drain regions of cell transistors and may be stacked in a vertical direction, a second electrode may penetrate through the first electrodes and may be electrically connected to a fixed voltage circuit, and the third electrode may penetrate through the first electrodes and may be electrically connected to a variable voltage circuit.

The semiconductor device may include the capacitor structure including the three electrodes, thereby increasing the integration degree of semiconductor devices, and increasing a sensing margin for sensing information.

Additionally, because the second and third electrodes penetrating through the first electrodes may serve as supports, deformation such as warpage of cell transistors and capacitor structures may be prevented.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1, 2A, and 2B are views conceptually illustrating an example of a semiconductor device according to an example embodiment of the present disclosure;

FIGS. 3 and 4 are views conceptually illustrating a modified example of a semiconductor device according to an example embodiment of the present disclosure;

FIG. 5A is a conceptual circuit diagram illustrating an example of a semiconductor device according to an example embodiment of the present disclosure;

FIG. 5B is a conceptual circuit diagram illustrating a modified example of a semiconductor device according to an example embodiment of the present disclosure;

FIG. 5C is a conceptual circuit diagram illustrating a modified example of a semiconductor device according to an example embodiment of the present disclosure;

FIG. 5D is a conceptual circuit diagram illustrating a modified example of a semiconductor device according to an example embodiment of the present disclosure;

FIG. 6A is a conceptual diagram illustrating an example of a semiconductor device according to an example embodiment of the present disclosure;

FIG. 6B is a conceptual diagram illustrating a modified example of a semiconductor device according to an example embodiment of the present disclosure;

FIG. 6C is a conceptual diagram illustrating a modified example of a semiconductor device according to an example embodiment of the present disclosure;

FIG. 6D is a conceptual diagram illustrating a modified example of a semiconductor device according to an example embodiment of the present disclosure;

FIG. 7A is a block diagram illustrating an example of a semiconductor device according to an example embodiment of the present disclosure;

FIG. 7B is a circuit diagram illustrating an example of a semiconductor device according to an example embodiment of the present disclosure;

FIG. 8A is a block diagram illustrating an example of a semiconductor device according to an example embodiment of the present disclosure;

FIGS. 8B to 8D are circuit diagrams illustrating an example of a semiconductor device according to an example embodiment of the present disclosure;

FIGS. 8E to 8G are circuit diagrams illustrating an example of a semiconductor device according to an example embodiment of the present disclosure;

FIG. 9A is a conceptual perspective view illustrating an example of a semiconductor device according to an example embodiment of the present disclosure;

FIG. 9B is a conceptual perspective view illustrating a modified example of a semiconductor device according to an example embodiment of the present disclosure;

FIG. 9C is a conceptual perspective view illustrating a modified example of a semiconductor device according to an example embodiment of the present disclosure;

FIG. 9D is a conceptual perspective view illustrating a modified example of a semiconductor device according to an example embodiment of the present disclosure;

FIG. 10A is a plan view illustrating an example of a semiconductor device according to an example embodiment of the present disclosure;

FIG. 10B is a plan view illustrating a modified example of a semiconductor device according to an example embodiment of the present disclosure;

FIG. 10C is a plan view illustrating a modified example of a semiconductor device according to an example embodiment of the present disclosure;

FIG. 10D is a plan view illustrating a modified example of a semiconductor device according to an example embodiment of the present disclosure;

FIG. 10E is a plan view illustrating a modified example of a semiconductor device according to an example embodiment of the present disclosure;

FIG. 10F is a plan view illustrating a modified example of a semiconductor device according to an example embodiment of the present disclosure;

FIG. 10G is a plan view illustrating a modified example of a semiconductor device according to an example embodiment of the present disclosure;

FIG. 10H is a plan view illustrating a modified example of a semiconductor device according to an example embodiment of the present disclosure;

FIG. 10I is a plan view illustrating a modified example of a semiconductor device according to an example embodiment of the present disclosure;

FIGS. 11A to 11D are perspective views illustrating an example of a method of forming a semiconductor device according to an example embodiment of the present disclosure; and

FIGS. 12A to 12G are views illustrating an example of a method of forming a semiconductor device according to an example embodiment of the present disclosure.

### DETAILED DESCRIPTION

Hereinafter, the terms such as “upper,” “intermediate,” and “lower” may be replaced with other terms such as “first,” “second,” and “third” and may be used to describe elements of the specification. The terms such as “first,” “second,” and “third” may be used to describe various elements, but the elements are not limited thereto, and the “first element” could be termed “second element.”

In the specification, it may be understood that the expressions such as “below”, “beneath,” “on,” “above,” “upper,” and “lower” may be described based on drawings.

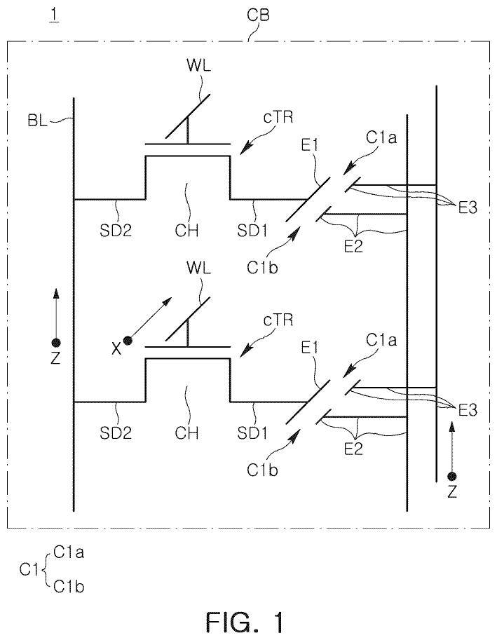

First, an example of a semiconductor device according to an example embodiment of the present disclosure will be described with reference to FIG. 1. FIG. 1 is a circuit diagram schematically illustrating a semiconductor device according to an example embodiment of the present disclosure.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Referring to FIG. 1, a semiconductor device 1 according to an example embodiment may include a plurality of cell blocks CB. Each of the plurality of cell blocks CB may include cell transistors cTR. Each of the cell transistors cTR may include a first source/drain region SD1, a second source/drain region SD2, and a channel region between the first source/drain region SD1 and the second source/drain region SD2, and a word line WL that may be a gate electrode.

Hereinafter, the description will focus on one cell block CB among the plurality of cell blocks CB.

The cell block CB may further include a bit line BL electrically connected to the second source/drain regions SD2 of the cell transistors cTR.

The cell block CB may further include a data storage structure C1 electrically connected to the first source/drain regions SD1 of the cell transistors cTR.

In an example embodiment, the data storage structure C1 may be a capacitor structure capable of storing information. Hereinafter, the data storage structure C1 will be described and referred to as a capacitor structure.

The data storage structure C1 may include first electrodes E1 respectively connected to the first source/drain regions SD1, second electrodes E2 facing the first electrodes E1, and third electrodes E3 facing the first electrodes E1 and spaced apart from the first electrodes E1.

Referring to FIG. 1, when describing one first electrode E1 of the first electrodes E1 as a reference, the first electrode E1, the corresponding second electrode E2, and the corresponding third electrode E3 may be included in a first capacitor C1a. Another first electrode E1, the corresponding second electrode E2, and the corresponding third electrode E3 may be included in a second capacitor C1b. Accordingly, the capacitor structure C1 may include the first capacitor C1a and the second capacitor C1b. Next, together with FIG. 1 described above, an example of a semiconductor

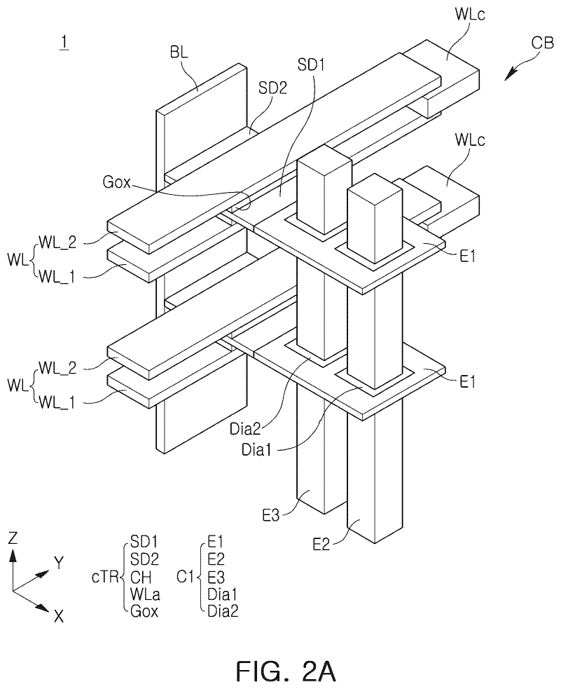

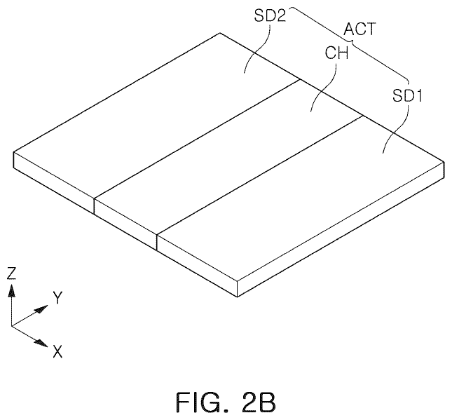

device according to an example embodiment of the present disclosure will be described with reference to FIGS. 2A and 2B. FIG. 2A is a conceptual perspective view illustrating a semiconductor device according to an example embodiment of the present disclosure, and FIG. 2B is a perspective view illustrating an active pattern ACT of FIG. 2A.

Referring to FIGS. 2A and 2B along with FIG. 1, the semiconductor device 1 may include active patterns ACT stacked and spaced apart from each other in a vertical direction (Z-direction).

Each of the activation patterns ACT may include the first source/drain region SD1, the second source/drain region SD2, and the channel region CH between the first source/drain region SD1 and the second source/drain region SD2 described in FIG. 1. The second source/drain region SD2, the channel region CH, and the first source/drain region SD1 may be sequentially arranged in a first horizontal direction (X-direction). Each of the active patterns ACT may have a bar shape extending in the first horizontal direction (X-direction). The first horizontal direction (X-direction) may be a first horizontal direction, perpendicular to the vertical direction (Z-direction).

An item, layer, or portion of an item or layer described as “extending” or as extending “lengthwise” in a particular direction has a length in the particular direction and a width perpendicular to that direction, where the length is greater than the width.

Two active patterns ACT stacked in the vertical direction (Z-direction) are illustrated in FIG. 2A, but the inventive concept is not limited thereto. The number of active patterns ACT stacked in the vertical direction (Z-direction) may be more than two.

The active patterns ACT may be semiconductor patterns formed of a semiconductor material. For example, each of the active patterns ACT may be formed of a silicon layer, but the inventive concept is not limited thereto, and each of the active patterns ACT may also be formed of other semiconductor materials.

The first and second source/drain regions SD1 and SD2 may have an N-type conductivity. The first source/drain regions SD1 may be stacked and spaced apart from each other in the vertical direction (Z-direction), and may overlap each other vertically. The second source/drain regions SD1 may be stacked and spaced apart from each other in the vertical direction (Z-direction), and may overlap each other vertically. The channel regions CH may be stacked and spaced apart from each other in the vertical direction (Z-direction), and may overlap each other vertically.

As described in FIG. 1, the capacitor structure C1 may be electrically connected to the first source/drain regions SD1. Accordingly, the capacitor structure C1 may be connected to the active patterns ACT.

The capacitor structure C1 may be a data storage structure capable of storing information in a semiconductor device including a memory such as DRAM.

The capacitor structure C1 may further include first dielectric layers Dia1 between the first electrodes E1 and the second electrode E2, and second dielectric layers Dia2 between the first electrodes E1 and the third electrode E3.

The first electrodes E1 that may be electrically connected to the corresponding first source/drain regions SD1 may be stacked and spaced apart from each other in the vertical direction (Z-direction), and may overlap each other vertically.

The second electrode E2 may have a side surface facing the first electrodes E1. For example, each of the side surfaces of the second electrode E2 may face the first electrodes E1. The second electrode E2 may extend in the vertical direction (Z-direction) and may penetrate through the first electrodes E1. The second electrode E2 may be a conductive pillar extending in the vertical direction (Z-direction).

The third electrode E3 may have a side surface facing the first electrodes E1. For example, each of the side surfaces of the third electrode E3 may face the first electrodes E1. The third electrode E3 may extend in the vertical direction (Z-direction) and may penetrate through the first electrodes E1. The third electrode E3 may be a conductive pillar extending in the vertical direction (Z-direction). The second electrode E2 may be spaced apart from the third electrode E3. Each of the first electrodes E1 may surround a side surface (e.g., side surfaces) of the second electrode E2 and a side surface (e.g., side surfaces) of the third electrode E3. Accordingly, each of the first electrodes E1 may have a ring shape surrounding the side surfaces of the second and third electrodes E2 and E3. The ring shape of each of the first electrodes E1 may have two holes through which the second electrode E2 and the third electrode E3 pass.

The second and third electrodes E2 and E3 may be formed simultaneously and may include the same conductive material.

Since the second and third electrodes E2 and E3 penetrating through the first electrodes E1 may serve as supports, deformation such as warpage of the cell transistors cTR and the capacitor structure C1 may be prevented.

Each of the second and third electrodes E2 and E3 may include a lower surface disposed at a lower level than a lowermost active pattern, among the active patterns ACT, and an upper surface disposed at a higher level than an uppermost active pattern, among the active patterns.

In example embodiments, one of the second electrode E2 and the third electrode E3 may be an electrode to which a fixed voltage is applied, and the other thereof may be an electrode to which a variable voltage is applied.

The bit line BL electrically connected to the second source/drain regions SD2 described in FIG. 1 may extend in the vertical direction (Z-direction). The bit line BL may be connected to the active patterns ACT.

The word lines WL described in FIG. 1 may be stacked and spaced apart from each other in the vertical direction (Z-direction). The word lines WL may vertically overlap the channel regions CH.

The semiconductor device 1 may further include gate dielectric layers Gox disposed between the word lines WL and the active patterns ACT.

Each of the cell transistors (cTR) described in FIG. 1 may include the first source/drain region SD1, the second source/drain region SD2, the channel region CH, the gate dielectric layer Gox, and the word line WL. The cell transistors cTR may be stacked in the vertical direction (Z-direction). The word lines WL may be gate electrodes.

In one channel region CH and one word line WL that are adjacent to each other, among the channel regions CH and the word lines WL, the word line WL may face at least one of a lower surface and an upper surface of the channel region CH. For example, the word line WL may include a first portion WL_1 disposed below the lower surface of the channel region CH, and a second portion WL_2 disposed on the upper surface of the channel region CH.

The semiconductor device 1 may further include gate connection patterns WLc connected to the word lines WL. For example, in one word line WL and one gate connection pattern WLc connected to each other, among the word lines WL and the gate connection patterns WLc, the gate connection pattern WLc may be connected to the first and second portions WLa_1 and WLa_2 of the word line WL.

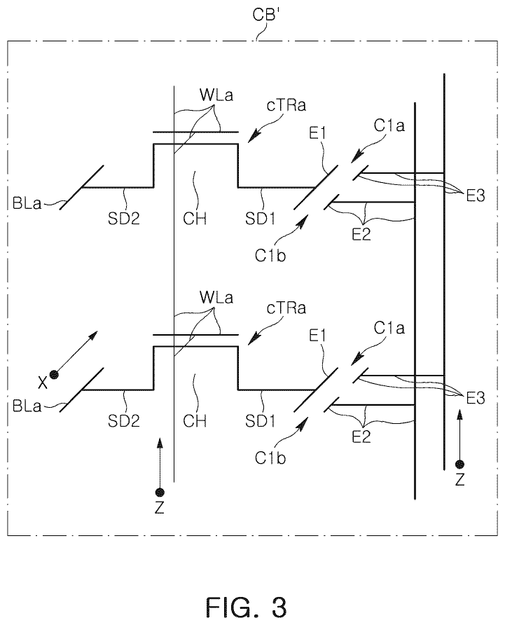

Next, a modified example of a semiconductor device according to an example embodiment of the present disclosure will be described with reference to FIG. 3. FIG. 3 is a circuit diagram illustrating a modified example of the word line WL and the bit line BL described in FIG. 1.

Referring to FIG. 3, the cell transistors cTR (see FIG. 1) including the word line WL (see FIG. 1) described above may be modified into cell transistors cTRa including a word line WLa as illustrated in FIG. 3. Each of the cell transistors cTRa may include the first source/drain region SD1, the channel region CH, and the second source/drain region SD2, as described in FIG. 1. The cell transistors cTRa may share the word line WLa.

The bit line BL (see FIG. 1) described above may be modified into separate bit lines BLa electrically connected to the second source/drain regions SD2, respectively, and spaced apart from each other, as illustrated in FIG. 3.

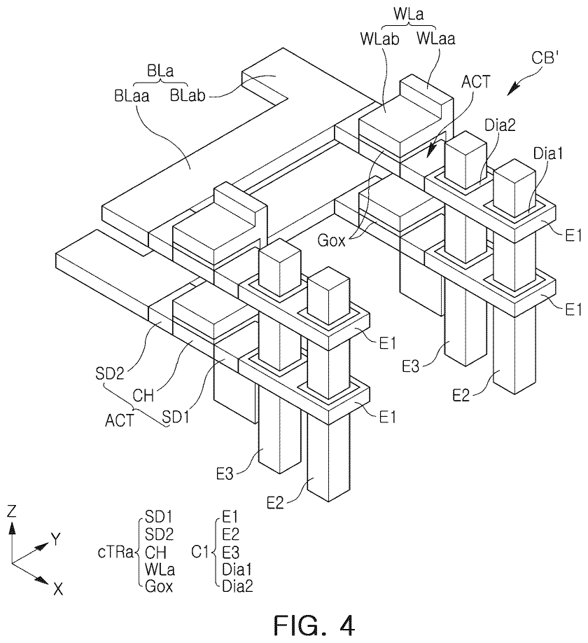

Next, a modified example of a semiconductor device according to an example embodiment of the present disclosure will be described with reference to FIG. 4 along with FIG. 3. FIG. 4 further illustrates that the active patterns ACT stacked in the vertical direction (Z-direction) in FIG. 2A are arranged in the second horizontal direction (Y-direction), and is a conceptual perspective view illustrating a modified example of the word lines WL (see FIG. 2A) and the bit lines BL (FIG. 2A) described in FIG. 2A.

Referring to FIG. 4 along with FIG. 3, the word line WL (see FIG. 2A) described above may be modified into word lines WLa as illustrated in FIG. 4.

Each of the word lines WLa may include a vertical portion WLaa extending in the vertical direction (Z-direction) and a protruding portion WLab extending in a horizontal direction from the vertical portion WLaa to vertically overlap the channel regions CH. The gate dielectric layers Gox described above may be disposed between each word line WLa and the corresponding active pattern ACT.

The bit line BL (see FIGS. 1 and 2A) described above may be modified into bit lines BLa as illustrated in FIGS. 3 and 4. The bit lines BLa may be respectively connected to the second source/drain regions SD2 sequentially arranged in the vertical direction (Z-direction). Each of the bit lines BLa may be connected to the second source/drain regions SD2 sequentially arranged in the second horizontal direction (Y-direction). Each of the bit lines BLa may include a line portion BLaa extending in the second horizontal direction (Y-direction) and electrically connected to the second source/drain regions SD2 disposed at the same level, and a pad portion BLab extending from the line portion BLaa in a direction away from the active patterns ACT.

The cell transistors cTR (see FIGS. 1 and 2) illustrated in FIGS. 1 and 2 may be modified into cell transistors cTRa as illustrated in FIGS. 3 and 4.

Each of the cell transistors cTRa includes the first source/drain region SD1, the second source/drain region SD2, the channel region CH, the gate dielectric layer Gox, and the word line WLa.

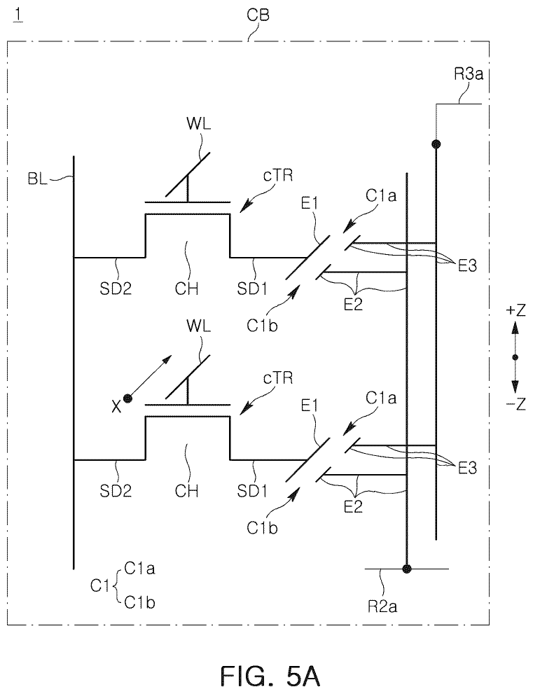

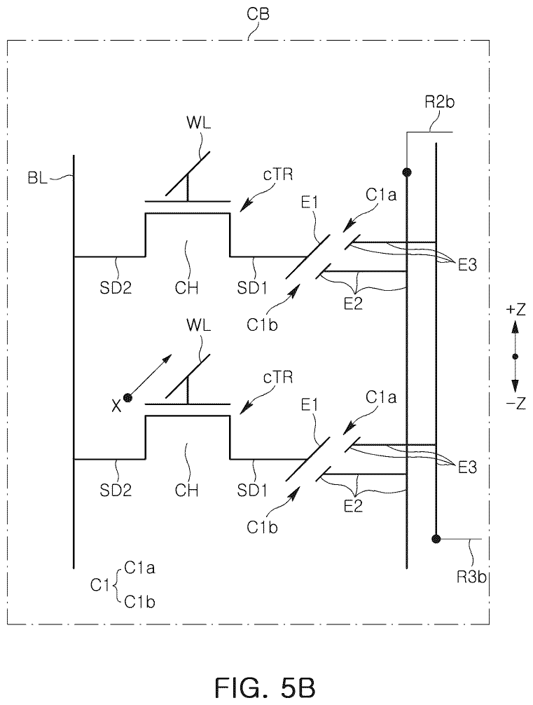

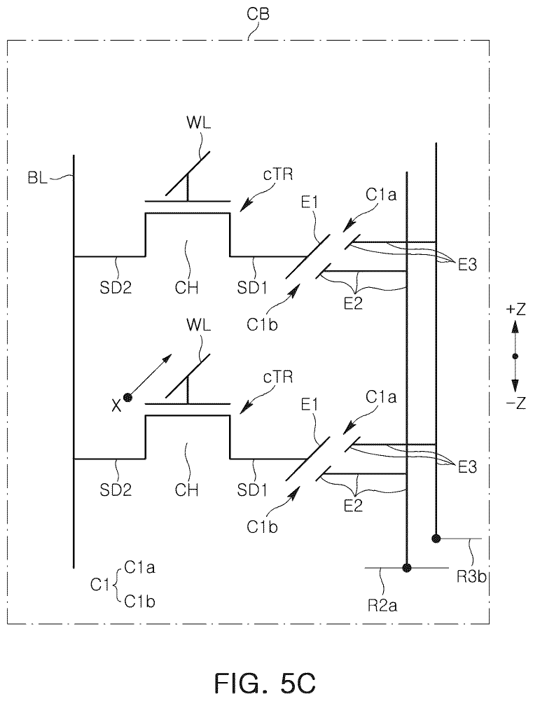

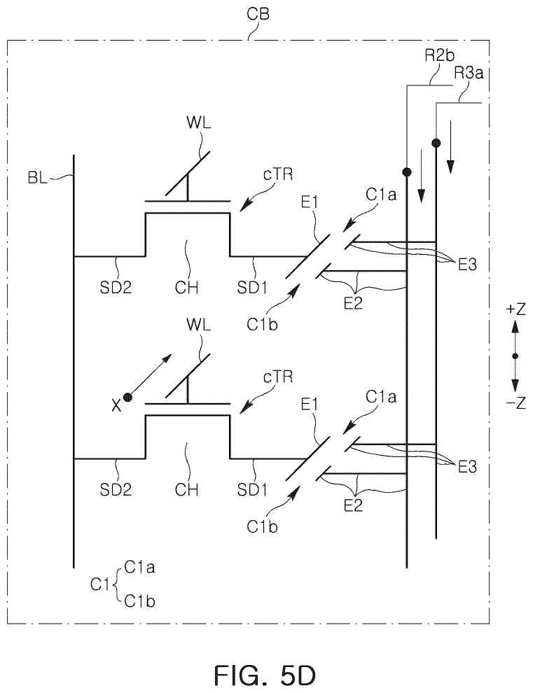

Next, referring to FIG. 5A, an example in which voltage is applied to the second electrode E2 (FIGS. 1, 2A, 3 and 4) and the third electrode E3 (FIGS. 1, 2A, 3 and 4) described above will be described. FIG. 5A is a circuit diagram illustrating a first routing interconnection structure R2a for applying voltage to the second electrode E2 and a second routing interconnection structure R3a for applying voltage to the third electrode E3 in the circuit of FIG. 1. In an example embodiment, first and second routing interconnection structures R2a and R3a that apply voltage in the circuit of FIG. 1 are illustrated, but the first and second routing interconnection structures R2a and R3a may be equally applied to FIGS. 2, 3 and 4.

In FIG. 5A, the vertical direction (Z-direction) may be described to be divided into a +Z direction directed from a lower surface to an upper surface of each of the second and third electrodes E2 and E3 and a −Z direction directed from the upper surface to the lower surface of each of the second and third electrodes E2 and E3. Here, the +Z direction may be a direction directed from a lowermost active pattern to an uppermost active pattern, among the active patterns ACT (see FIG. 3), and the −Z direction may be a direction directed from the uppermost active pattern to the lowermost active pattern, among the active patterns ACT (see FIG. 3).

Referring to FIG. 5A, the semiconductor device 1 may further include a first routing interconnection structure R2a electrically connected to the second electrode E2 to apply fixed voltage, and a second routing interconnection structure R3a electrically connected to the third electrode E3 to apply variable voltage.

The first routing interconnection structure R2a may be connected to a lower end of the second electrode E2. Accordingly, the first routing interconnection structure R2a may be connected to a lower end of the second electrode E2 to apply voltage to the second electrode E2 in the +Z direction. The second routing interconnection structure R3a may be connected to an upper end of the third electrode E3. Accordingly, the second routing interconnection structure R3a may be connected to the upper end of the third electrode E3 to apply voltage to the third electrode E3 in the −Z direction.

Accordingly, the second and third electrodes E2 and E3 of the cell block CB may be electrically connected to the first and second routing interconnection structures R2a and R3a, respectively.

Next, referring to FIGS. 5B, 5C and 5D, respectively, various modified examples of the first routing interconnection structure R2a (see FIG. 5A) and the second routing interconnection structure R3a (see FIG. 5A) described in FIG. 5A will be described. FIGS. 5B, 5C and 5D are circuit diagrams illustrating various modified examples of the first routing interconnection structure R2a (FIG. 5A) and the second routing interconnection structure R3a (FIG. 5A) described in FIG. 5A.

In a modified example, referring to FIG. 5B, the first routing interconnection structure R2a (see FIG. 5A) shown in FIG. 5A may be modified into a first routing interconnection structure R2b connected to an upper end of the second electrode E2, and the second routing interconnection structure R3a (FIG. 5A) shown in FIG. 5A may be modified into a second routing interconnection structure R3b connected to a lower end of the third electrode E3. The first routing interconnection structure R2b may be connected to the upper end of the second electrode E2 to apply voltage to the second electrode E2 in the −Z direction. The second routing interconnection structure R3b may be connected to the lower end of the third electrode E3 to apply voltage to the third electrode E3 in the +Z direction.

In a modified example, referring to FIG. 5C, as shown in FIG. 5A, the first routing interconnection structure R2a may be connected to the lower end of the second electrode E2 to apply voltage to the second electrode E2 in the +Z direction, and as shown in FIG. 5B, the second routing interconnection structure R3b may be connected to the lower end of the third electrode E3 to apply voltage to the third electrode E3 in the +Z direction.

In a modified example, referring to FIG. 5D, as shown in FIG. 5B, the first routing interconnection structure R2b may be connected to the upper end of the second electrode E2 to apply voltage to the second electrode E2 in the −Z direction, and as shown in FIG. 5A, the second routing interconnection structure R3a may be connected to the upper end of the third electrode E3 to apply voltage to the third electrode E3 in the −Z direction.

In the above-described example embodiments, one of the second electrode E2 and the third electrode E3 may be an electrode to which fixed voltage is applied, and the other thereof may be an electrode to which variable voltage is applied. Hereinafter, the second electrode E2 will be described as an electrode to which fixed voltage is applied, and the third electrode E3 will be described as an electrode to which variable voltage is applied.

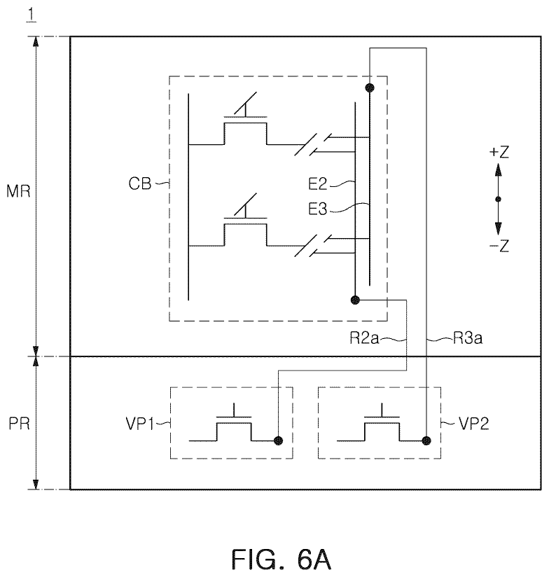

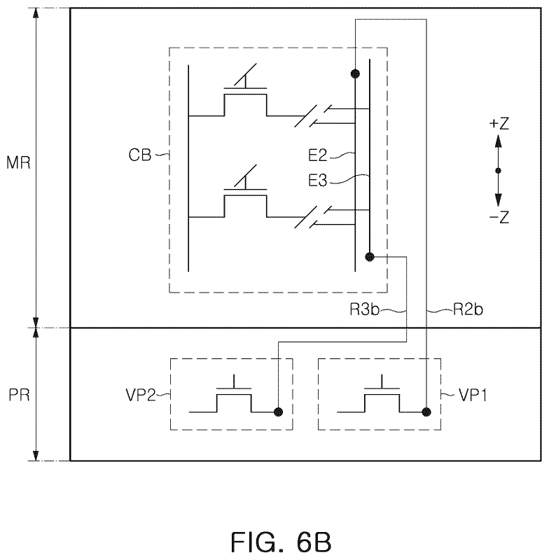

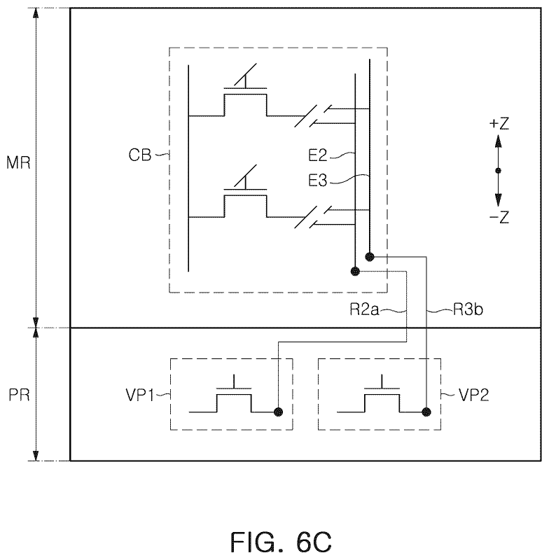

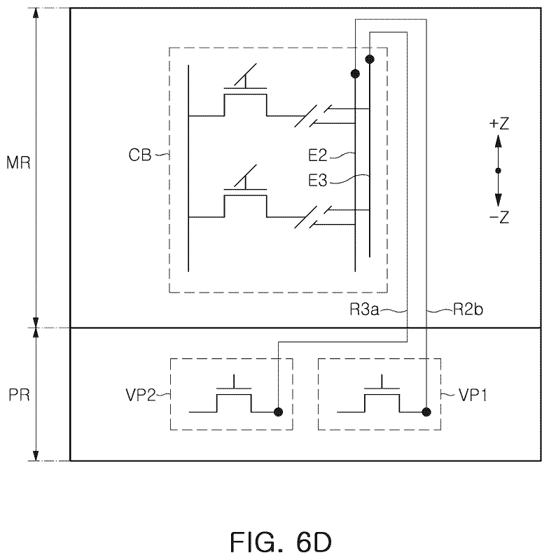

Next, referring to FIG. 6A along with FIG. 5A, an example of a semiconductor device according to an example embodiment of the present disclosure will be described.

FIG. 6A is a conceptual diagram illustrating an example of a semiconductor device according to an example embodiment of the present disclosure.

Referring to FIG. 6A together with FIG. 5A, the semiconductor device 1 may include a memory region MR including the cell block CB and the first and second routing interconnection structures R2a and R3a, and a peripheral circuit region PR vertically overlapping the memory region MR. The memory region MR may be disposed on the peripheral circuit region PR.

The peripheral circuit region PR may include a fixed voltage supply circuit VP1 for applying the fixed voltage to the second electrode E2 in the memory region MR, and a variable voltage supply circuit VP2 for applying the variable voltage to the third electrode E3 in the memory region MR.

The first routing interconnection structure R2a may extend into the peripheral circuit region PR and may be electrically connected to the fixed voltage supply circuit VP1. The second routing interconnection structure R3a may extend into the peripheral circuit region PR and may be electrically connected to the variable voltage supply circuit VP2. Each of the first and second routing interconnection structures R2a and R3a may be formed using a conductive pad, a conductive via, and a conductive interconnection.

The first routing interconnection structure R2a may electrically connect the lower end of the second electrode E2 to the fixed voltage supply circuit VP1, and the second routing interconnection structure R3a may electrically connect the upper end of the third electrode E3 to the variable voltage supply circuit VP2.

Next, referring to FIG. 6B, an electrical connection relationship between the first and second routing interconnection structures R2b and R3b shown in FIG. 5B and the variable voltage supply circuit VP2 and the fixed voltage supply circuit VP1 shown in FIG. 6A is described.

Referring to FIG. 6B together with FIG. 5B, the first routing interconnection structure R2b may electrically connect the upper end of the second electrode E2 to the fixed voltage supply circuit VP1, and the second routing interconnection structure R3b may electrically connect the lower end of the third electrode E3 to the variable voltage supply circuit VP2.

Next, referring to FIG. 6C, an electrical connection relationship between the first and second routing interconnection structures R2a and R3b shown in FIG. 5C and the variable voltage supply circuit VP2 and the fixed voltage supply circuit VP1 shown in FIG. 6A is described.

Referring to FIG. 6C together with FIG. 5C, the first routing interconnection structure R2a may electrically connect the lower end of the second electrode E2 to the fixed voltage supply circuit VP1, and the second routing interconnection structure R3b may electrically connect the lower end of the third electrode E3 to the variable voltage supply circuit VP2.

Next, referring to FIG. 6D, an electrical connection relationship between the first and second routing interconnection structures R2b and R3a shown in FIG. 5D and the variable voltage supply circuit VP2 and the fixed voltage supply circuit VP1 shown in FIG. 6A is described.

Referring to FIG. 6D together with FIG. 5D, the first routing interconnection structure R2b may electrically connect the upper end of the second electrode E2 to the fixed voltage supply circuit VP1, and the second routing interconnection structure R3a may electrically connect the upper end of the third electrode E3 to the variable voltage supply circuit VP2.

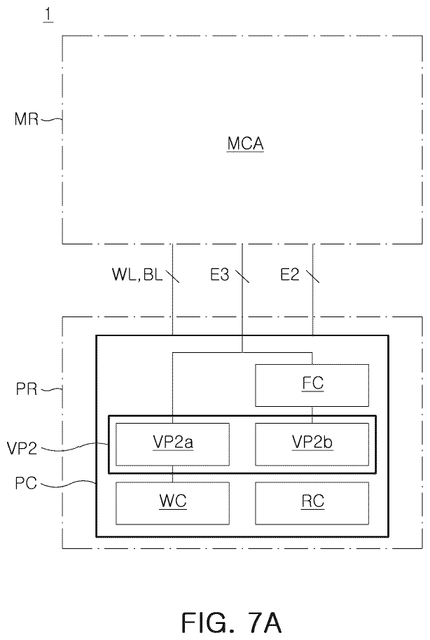

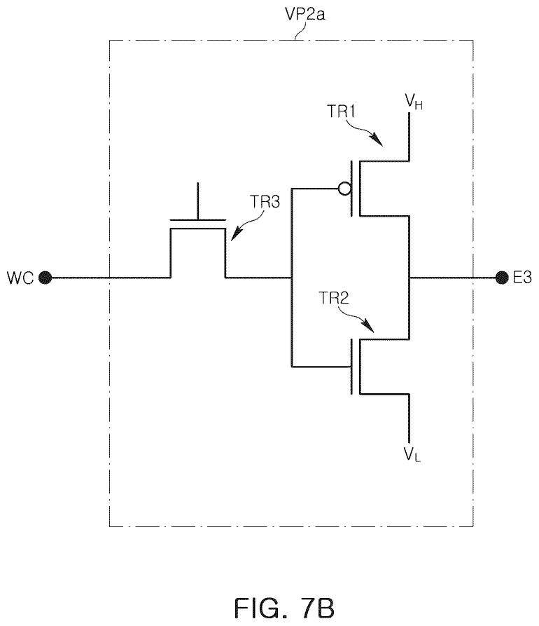

Next, referring to FIGS. 7A and 7B, an example of a semiconductor device according to an example embodiment of the present disclosure will be described. FIG. 7A is a block diagram illustrating an example of a semiconductor device according to an example embodiment of the present disclosure, and FIG. 7B is a circuit diagram illustrating an example of the variable voltage supply circuit VP2.

Referring to FIGS. 7A and 7B, the memory region MR of any of the example embodiments of FIGS. 6A to 6D may include a memory cell array region MCA including the plurality of cell blocks CB, and the peripheral circuit region PR of any of the example embodiments of FIGS. 6A to 6D may include a peripheral circuit PC.

The variable voltage supply circuit VP2 may include a first voltage supply circuit VP2a and a second voltage supply circuit VP2b.

The peripheral circuit PC may include a write circuit WC for performing a write operation, and the first voltage supply circuit VP2a of the variable voltage supply circuit VP2 electrically may be connected to the writing circuit WC.

The writing circuit WC and the first voltage supply circuit VP2a of the variable voltage supply circuit VP2 may be circuits for storing data in the capacitor structures C1 of the plurality of cell blocks CB.

In an example embodiment, a unit memory cell cTR, C1 (see FIG. 1) of the cell block CB may be comprised of one cell transistor cTR (see FIG. 1) and one capacitor structure C1 connected to the one cell transistor cTR.

Storing “1” data in the unit memory cell cTR, C1 (see FIG. 1) in the write circuit WC may be performed in a manner in which, in a state in which Vp voltage, that is, fixed voltage, is applied to the second electrode E2, the cell transistor cTR (see FIG. 1) is turned on, and then, in order to charge the capacitor structure C1 with electric charges, Vdd voltage is applied to the bit line BL (see FIG. 1) to save “1” data, and when the cell transistor cTR (see FIG. 1) is turned off, the saved “1” data is stored.

Storing “0” data in the unit memory cell cTR, C1 (see FIG. 1) in the write circuit WC may be performed in a manner in which, in a state in which the fixed voltage is applied to the second electrode E2, the cell transistor cTR (see FIG. 1) is turned on, and in order to discharge the electric charges of the capacitor structure C1, voltage, for example, 0V, is applied to the bit line BL (see FIG. 1) to save “0” data, and when the cell transistor cTR (see FIG. 1) is turned off, the saved “0” data may be stored.

The first voltage supply circuit VP2a of the variable voltage supply circuit VP2 may be a circuit for providing variable voltage to the third electrode E3 during the write operation. For example, the first voltage supply circuit VP2a of the variable voltage supply circuit VP2 may be electrically connected to the writing circuit WC and the second routing interconnection structure R3a, and may provide the variable voltage to the third electrode E3, between the writing circuit WC of the peripheral circuit PC and the second routing interconnection structure R3a. The second routing interconnection structure R3a may be the same as that described in FIGS. 6A and 6D, but the inventive concept is not limited thereto. For example, the second routing interconnection structure R3a may be replaced with the second routing interconnection structure R3b described in FIGS. 6B and 6C.

The first voltage supply circuit VP2a of the variable voltage supply circuit VP2 may include a PMOS transistor TR1 and a first NMOS transistor TR2 in which sources are connected to each other and gates are connected to each other. The sources connected to each other of the PMOS transistor TR1 and the first NMOS transistor TR2 may be electrically connected to the second routing interconnection structure R3a. A drain of the PMOS transistor TR1 may be connected to V_{H} voltage, and a drain of the first NMOS transistor TR2 may be connected to V_{L} voltage. The first voltage supply circuit VP2a of the variable voltage supply circuit VP2 may further include a second NMOS transistor TR3 between the writing circuit WC and gates connected to each other of the PMOS transistor TR1 and the first NMOS transistor TR2.

The fixed voltage applied to the second electrode E2 may be a first positive voltage, the V_{H} voltage may be a second positive voltage different from the first positive voltage, and the V_{L} voltage may be a negative voltage. The first positive voltage may be higher than the second positive voltage.

TABLE 1

| | Applying V_{H} voltage to the | Applying V_{L} voltage to the |
|---|---|---|
| | third electrode | third electrode |
| D0 | G | W |
| D1 | W | G |

Table 1 above may show that in a cell block CB in the memory cell array region MCA, during the write operation, when data is “0” or data is “1,” operation characteristics may be displayed according to the voltage applied to the third electrode E3 (see FIG. 1). Here, among “W” and “G,” “G” may mean better operating characteristics than “W.” The operating characteristic may be a sensing margin. Thus, as shown in Table 1, when writing “0” to the cell block CB, the sensing margin when applying voltage V_{H} to the third electrode is better than the sensing margin when applying voltage V_{L} to the third electrode. Further, when writing “1” to the cell block CB, the sensing margin when applying voltage V_{L} to the third electrode is better than the sensing margin when applying voltage V_{H} to the third electrode.

During the write operation, when “0” data is being stored in the capacitor structure C1 of the unit memory cell cTR, C1 (see FIG. 1), the operating characteristics may be improved when the V_{H} voltage is applied to the third electrode E3, as compared to when the V_{L} voltage is applied to the third electrode E3. Accordingly, during the write operation, in the case of storing information “0” in the capacitor structure C1 of a unit memory cell, in order to improve the operating characteristics, the variable voltage supply circuit VP2 may apply the V_{H} voltage to the third electrode E3 through the second routing interconnection structure R3a.

During the write operation, when “1” data is being stored in the capacitor structure C1 of the unit memory cell cTR, C1 (see FIG. 1), the operating characteristics may be improved when the V_{L} voltage is applied to the third electrode E3, as compared to when the V_{H} voltage is applied to the third electrode E3. Accordingly, during the write operation, when “1” data is stored in the capacitor structure C1 of the unit memory cell cTR, C1 (see FIG. 1), in order to improve the operating characteristics, the variable voltage supply circuit VP2 may apply the V_{L} voltage to the third electrode E3 through the second routing interconnection structure R3a.

In example embodiments, during the write operation, when storing “0” data in the capacitor structure C1 of the unit memory cell cTR, C1 (see FIG. 1), the V_{H} voltage applied to the third electrode E3 may be about +0.1V to about +0.3V.

In example embodiments, during the write operation, when storing “1” data in the capacitor structure C1 of the unit memory cell cTR, C1 (see FIG. 1), the V_{L} voltage applied to the third electrode E3 may be about-0.1V to about-0.3V.

In example embodiments, during read and write operations, the fixed voltage applied to the second electrode E2 may be about +0.5V to about +0.6V.

The peripheral circuit PC may further include a read circuit RC for performing a read operation. When the cell blocks CB (see FIGS. 1 and 2A) are in an off state, the peripheral circuit PC may further include voltage control circuits FC for supplying an optimized voltage to each of the turned-off cell blocks CB, and/or supplying an optimized offset voltage to the third electrode E3 during the read operation using the read circuit RC. Accordingly, the voltage control circuits FC may be used when the cell blocks CB (see FIGS. 1 and 2A) are in an off state or may be used during the read operation.

In one example, in order to read data stored in the unit memory cell cTR, C1 (see FIG. 1) using the read circuit RC, in a state in which the fixed voltage is applied to the second electrode E2, when the cell transistor cTR (see FIG. 1) is turned on and ½ Vdd voltage is applied to the bit line BL (see FIG. 1), the bit line BL (see FIG. 1) may be connected to the capacitor C1 (see FIG. 1), and when the capacitor structure C1 is charged with electric charges, the ½ Vdd voltage of the bit line BL may slightly increase, and when the capacitor structure C1 is discharged, the ½ Vdd voltage of the bit line BL may slightly decrease. The slight voltage change, that is, a potential difference, of the bit line BL may be amplified by a sense amplifier of the peripheral circuit PC, and thus, when the potential difference of the bit line BL increases, “1” data may be read as being stored, and when the potential difference of the bit line BL decreases, “0” data may be read as being stored.

During the write and read operations as described above, the Vp voltage, that is, fixed voltage, may be applied to the second electrode E2 by the fixed voltage supply circuit VP1 (FIG. 6A) in the peripheral circuit PC.

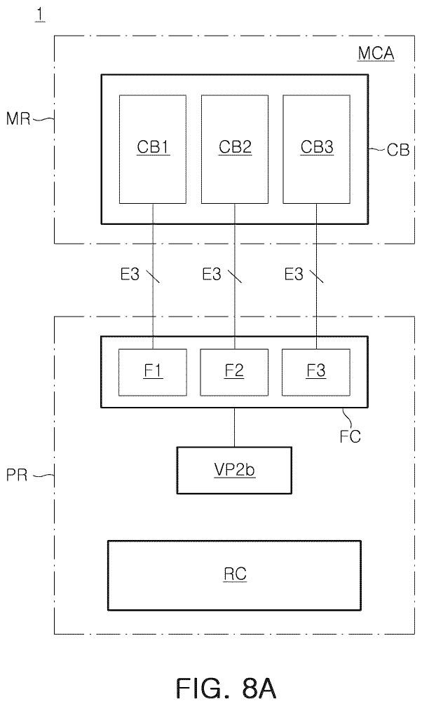

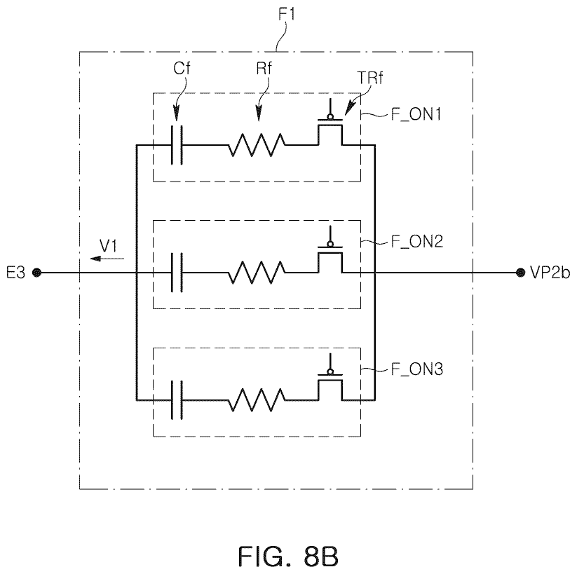

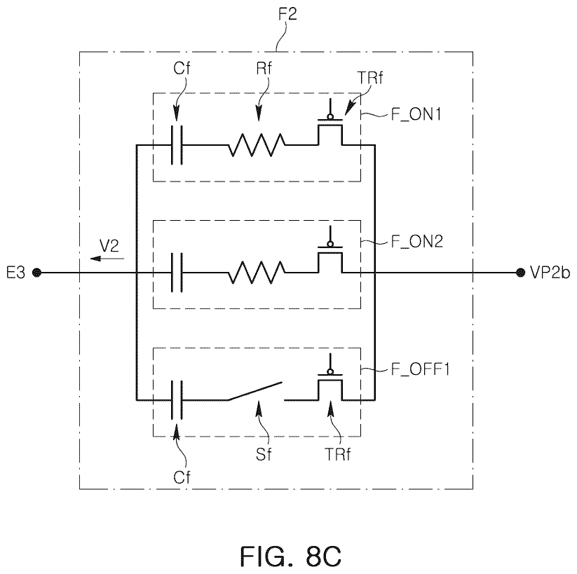

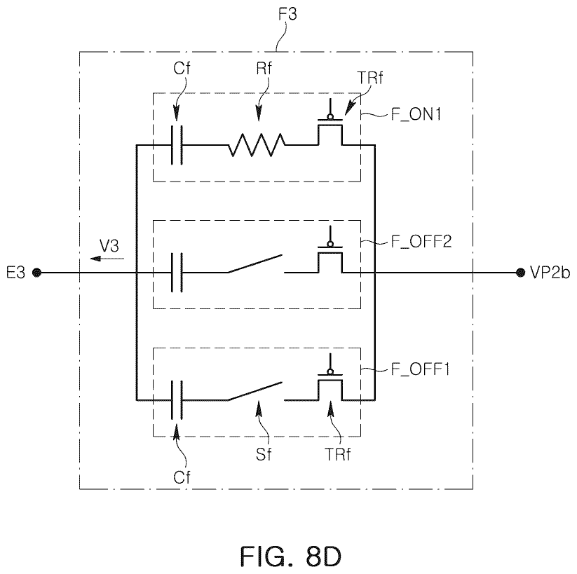

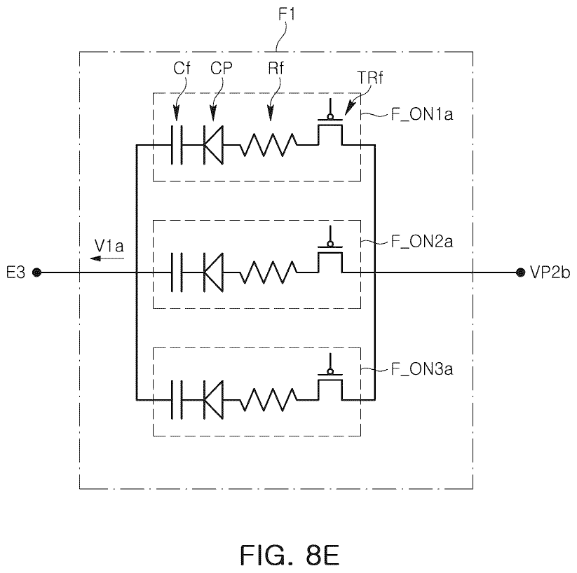

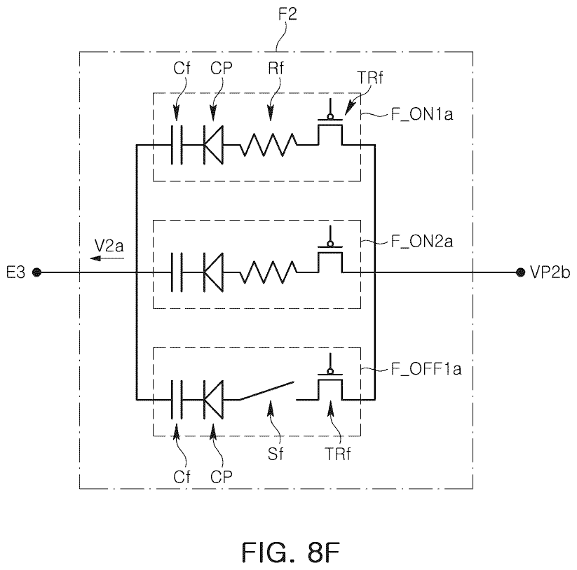

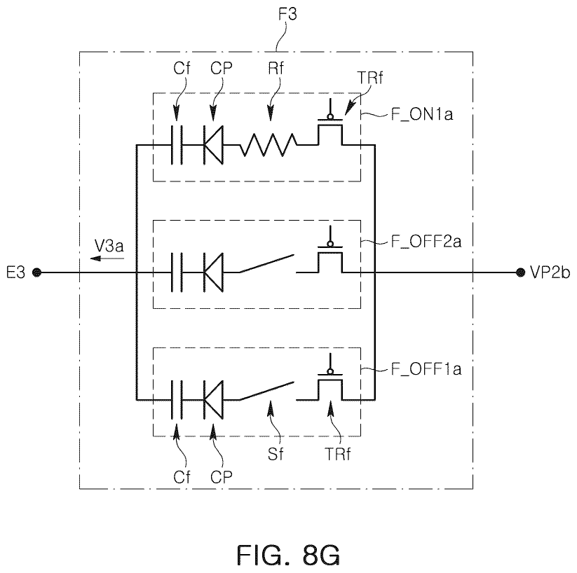

During the read operation, in order to increase the sensing margin, an optimal offset voltage may be applied to the third electrode E3 using the voltage control circuits FC. In this manner, examples of applying an optimal voltage to the third electrode E3 using the voltage control circuits FC when the cell blocks (CB in FIGS. 1 and 2A) are in an off state or during the read operation will be described referring to FIGS. 8A, 8B, 8C, 8D and 8E. FIG. 8A is a block diagram illustrating an example of a semiconductor device according to an example embodiment of the present disclosure, FIG. 8B is a circuit diagram illustrating an example of a first voltage control circuit F1 of FIG. 8A, FIG. 8C is a circuit diagram illustrating an example of a second voltage control circuit F2 of FIG. 8A, FIG. 8D is a circuit diagram illustrating an example of a third voltage control circuit F3 of FIG. 8A, FIG. 8E is a circuit diagram illustrating a modified example of the first voltage control circuit F1 of FIG. 8B, FIG. 8F is a circuit diagram illustrating a modified example of the second voltage control circuit F2 of FIG. 8C, and FIG. 8G is a circuit diagram illustrating a modified example of the third voltage control circuit F3 of FIG. 8D.

First, referring to FIGS. 8A, 8B, 8C and 8D along with FIG. 7A, the memory cell array region MCA in FIG. 7A may include a plurality of cell blocks CB. For example, the memory cell array region MCA may include a first cell block CB1, a second cell block CB2, and a third cell block CB3.

In one example, the voltage control circuits FC may be provided to apply an optimal offset voltage to the third electrodes E3 connected to the first, second, and third cell blocks CB1, CB2, and CB3 during the read operation.

Each of the voltage control circuits FC may include one or more unit voltage control cells F_ON1, F_ON2, F_ON3, F_OFF1 and F_OFF2 connected in parallel. Each of the unit voltage control cells F_ON1, F_ON2, F_ON3, F_OFF1 and F_OFF2 may include a capacitor Cf, a fuse Rf or Sf, and a transistor TRf connected in series.

In one example, the transistor TRf may be turned on during the read operation and may be turned off during the write operation.

In one example, the transistor TRf may be turned on when the cell blocks CB are turned off.

Terminals of the voltage control circuits FC adjacent to the capacitor Cf may be electrically connected to the third electrode E3, and terminals of the voltage control circuits FC adjacent to the transistor TRf may be electrically connected to the second voltage supply circuit VP2b of the variable voltage supply circuit VP2.

Depending on the state of the fuse Rf or Sf, the unit voltage control cells F_ON1, F_ON2, F_ON3, F_OFF1 and F_OFF2 may include first unit voltage control cells F_ON1, F_ON2 and F_ON3 in an on state and second unit voltage control cells F_OFF1 and F_OFF2 in an off state.

The unit voltage control cells F_ON1, F_ON2, F_ON3, F_OFF1 and F_OFF2 may use a MOSFET fuse. For example, the second unit voltage control cells F_OFF1 and F_OFF2 may include a fuse Sf in which the MOSFET fuse is cut off, that is, in an off state, and the first unit voltage control cells F_ON1, F_ON2 and F_ON3 may include a fuse Rf in which the MOSFET fuse is in an on state. The voltage control circuits FC may include the same number of unit voltage control cells as each other, and at least some of the voltage control circuits FC may include both a unit voltage control cell in an on state and a unit voltage control cell in an off state.

The voltage control circuits FC may include a first voltage control circuit F1 electrically connected to the third electrode E3 of the first cell block CB1, a second voltage control circuit F2 electrically connected to the third electrode E3 of the second cell block CB2, and a third voltage control circuit F3 electrically connected to the third electrode E3 of the third cell block CB3.

The first voltage control circuit F1 may include the first unit voltage control cells F_ON1, F_ON2 and F_ON3 in an on state. The first voltage control circuit F1 may apply a first voltage V1 to the third electrodes E3 of the first cell block CB1.

The second voltage control circuit F2 may include the first unit voltage control cells F_ON1 and F_ON2 and the second unit voltage control cell F_OFF1. The second voltage control circuit F2 may apply a second voltage V2 different from the first voltage V1 to the third electrodes E3 of the second cell block CB2.

The third voltage control circuit F3 may include the first unit voltage control cell F_ON1 and the second unit voltage control cells F_OFF1 and F_OFF2. The third voltage control circuit F3 may apply a third voltage V3 different from the first and second voltages V1 and V2 to the third electrodes E3 of the third cell block CB3.

Depending on the distribution of the semiconductor process, optimal voltages required for the cell blocks CB may vary. Accordingly, the number of the second unit voltage control cells F_OFF1 and F_OFF2 in an off state, among the unit voltage control cells F_ON1, F_ON2, F_ON3, F_OFF1 and F_OFF2 of the voltage control circuits FC may vary, depending on the optimal voltages required for the cell blocks CB. For example, the first voltage control circuit F1 may not have a unit cell in an off state, the second voltage control circuit F2 may include ‘m’ number of second unit voltage control cells F_OFF1, and the third voltage control circuit F3 may include ‘n’ number of second unit voltage control cells F_OFF1 and F_OFF2. The ‘n’ and ‘m’ may be different natural numbers. The ‘n’ may be larger than ‘m.’

During the read operation described above, an optimal offset voltage may be provided to the third electrode E3 using the voltage control circuits FC in which the number of the second unit voltage control cells F_OFF1 and F_OFF2 in the off state as described above is controlled. For example, during the read operation, the first voltage V1, the second voltage V2 or the third voltage V3 may be applied to the third electrodes E3 of the cell blocks CB using the voltage control circuits FC.

When the cell blocks CB described above are turned off, in order to provide optimal fixed voltages required for the cell blocks CB generated according to the distribution of the semiconductor process, a first fixed voltage may be applied to the second electrodes E2 of the cell blocks CB using the fixed voltage supply circuit VP1, the second voltage supply circuit VP2b of the variable voltage supply circuit VP2 may provide a second fixed voltage, and the second fixed voltage provided from the second voltage supply circuit VP2b may be provided as an optimal fixed voltage to the third electrodes E3 of each of the cell blocks CB, using the voltage control circuits FC in which the number of second unit voltage control cells F_OFF1 and F_OFF2 is adjusted. For example, when the cell blocks CB are turned off, the first voltage V1 may be applied to the third electrodes E3 of the first cell block CB1 using the voltage control circuits FC, the second voltage V2 may be applied to the third electrodes E3 of the second cell block CB2, and the third voltage V3 may be applied to the third electrodes E3 of the third cell block CB3.

In a modified example, referring to FIGS. 8E, 8F and 8G along with FIGS. 7A and 8A, in the voltage control circuits FC described above, each of the unit voltage control cells may further include a charge pump CP for stable pumping. For example, each of the voltage control circuits FC may include one or more unit voltage control cells F_ON1a, F_ON2a, F_ON3a, F_OFF1a and F_OFF2a connected in parallel, and each of the unit voltage control cells F_ON1a, F_ON2a, F_ON3a, F_OFF1a and F_OFF2a may include the capacitor Cf, the charge pump CP, the fuse Rf or Sf, and the transistor TRf connected in series.

The first voltage control circuit F1 may include the first unit voltage control cells F_ON1a, F_ON2a and F_ON3a in an on state. The first voltage control circuit F1 may apply a first voltage V1a to the third electrodes E3 of the first cell block CB1.

The second voltage control circuit F2 may include the first unit voltage control cells F_ON1a and F_ON2a in an on state and the second unit voltage control cell F_OFF1a in an off state. The second voltage control circuit F2 may apply a second voltage V2a different from the first voltage V1a to the third electrodes E3 of the second cell block CB2.

The third voltage control circuit F3 may include the first unit voltage control cell F_ON1a in an on state and the second unit voltage control cells F_OFF1a and F_OFF2a in an off state. The third voltage control circuit F3 may apply a third voltage V3a different from the first and second voltages V1a and V2a to the third electrodes E3 of the third cell block CB3.

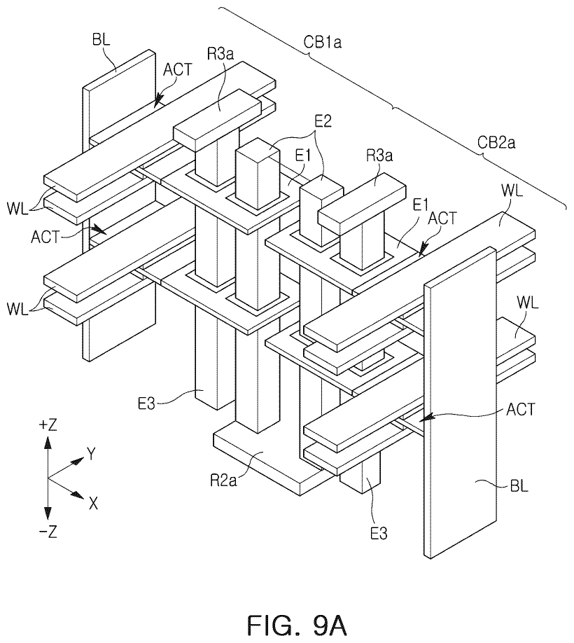

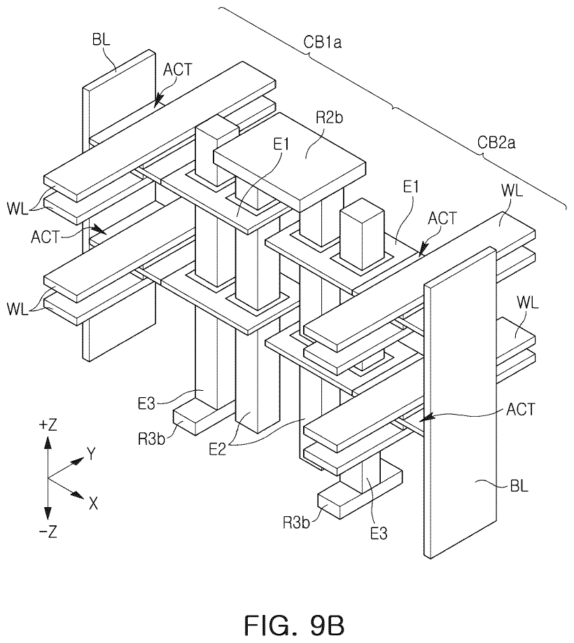

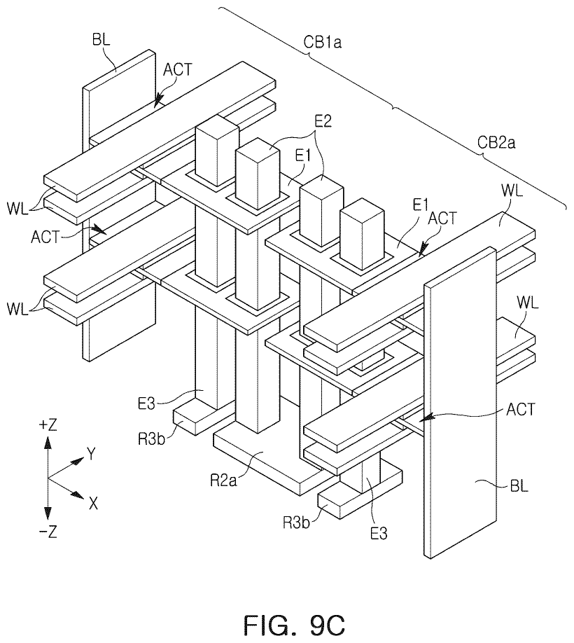

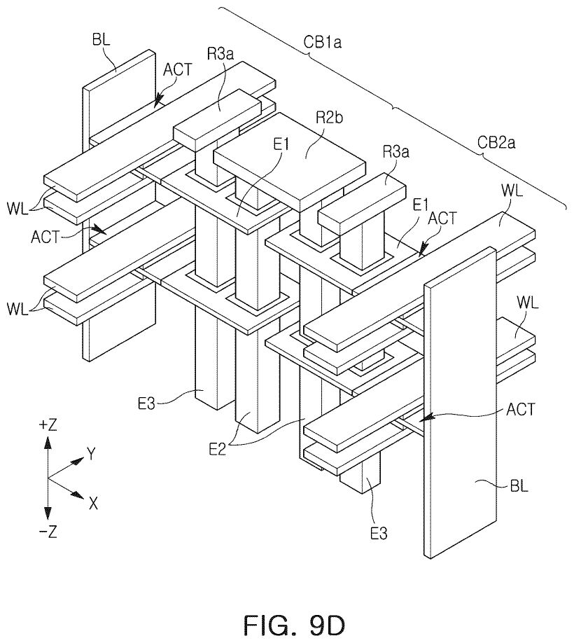

Next, referring to FIG. 9A along with FIGS. 1 to 5A, examples of routing interconnection structures of a first cell block CB1a and a second cell block CB2a disposed adjacently to each other will now be described. FIG. 9A is a conceptual perspective view illustrating routing interconnection structures of the first cell block CB1a and the second cell block CB2a disposed adjacently to each other.

In one example, referring to FIG. 9A, along with FIGS. 2A and 5A, a semiconductor device 1 according to an example embodiment may include a first cell block CB1a having the same structure as the cell block CB described in FIG. 2A or the same structure as the cell block CB′ described in FIG. 4, and a second cell block CB2a having a mirror symmetrical structure to the first cell block CB1a. The first electrodes E1 of the first cell block CB1a and the first electrodes E1 of the second cell block CB2a may face each other. The second electrode E2 may be an electrode to which a fixed voltage is applied, and the third electrode E3 may be an electrode to which a variable voltage is applied.

The first routing interconnection structure R2a described in FIG. 5A may be connected to a lower surface of the second electrode E2 of the first cell block CB1a and the lower surface of the second electrode E2 of the second cell block CB2a. The second routing interconnection structure R3a described in FIG. 5A may include a second routing interconnection structure R3a connected to an upper surface of the third electrode E3 of the first cell block CB1a, and a second routing interconnection structure R3a connected to the upper surface of the third electrode E3 of the second cell block CB2a. The second routing interconnection structure R3a connected to the upper surface of the third electrode E3 of the first cell block CB1a and the second routing interconnection structure R3a connected to the upper surface of the third electrode E3 of the second cell block CB2a may be separated from each other.

Next, referring to FIGS. 9B, 9C and 9D, along with FIGS. 1 to 5D, various modified examples of the first and second routing interconnection structures R2a and R3a described in FIG. 9A will now be described. FIGS. 9B, 9C, and 9D are conceptual perspective views illustrating routing interconnection structures of the first cell block CB1a and the second cell block CB2a disposed adjacently to each other.

In a modified example, referring to FIG. 9B along with FIGS. 2A and 5B, the first routing interconnection structure R2a (see FIG. 9A) described in FIG. 9A may be modified into a first routing interconnection structure R2b connected to an upper surface of the second electrode E2 of the first cell block CB1a and an upper surface of the second electrode E2 of the second cell block CB2a. The second routing interconnection structures R3a described in FIG. 9A may be modified into a second routing interconnection structure R3b connected to a lower surface of the third electrode E3 of the first cell block CB1a and a second routing interconnection structure R3b connected to a lower surface of the third electrode E3 of the second cell block CB2a.

In a modified example, referring to FIG. 9C along with FIGS. 2A and 5C, as described in FIG. 9A, the first routing interconnection structure R2a may be connected to the lower surface of the second electrode E2 of the first cell block CB1a and the lower surface of the second electrode E2 of the second cell block CB2, and the second routing interconnection structures R3a (see FIG. 9A) described in FIG. 9A may be modified into a second routing interconnection structure R3b connected to the lower surface of the third electrode E3 of the first cell block CB1a, and a second routing interconnection structure R3b connected to the lower surface of the third electrode E3 of the second cell block CB2a.

In a modified example, referring to FIG. 9D along with FIGS. 2A and 5D, the first routing interconnection structure R2a (see FIG. 9A) described in FIG. 9A may be modified into a first routing interconnection structure R2b connected to the upper surface of the second electrode E2 of the first cell block CB1a and the upper surface of the second electrode E2 of the second cell block CB2a, and as described in FIG. 9A, the second routing interconnection structures R3a may include a second routing interconnection structure R3a connected to the upper surface of the third electrode E3 of the first cell block CB1a, and a second routing interconnection structure R3a connected to an upper surface of the third electrode E3 of the second cell block CB2a.

In the capacitor structure C1 (see FIG. 2A) described above, the third electrode E3 and the second electrode E2 may be sequentially arranged in a direction away from the active pattern ACT, and each of the third electrodes E3 and the second electrode E2 may be square or substantially square, or have a shape similar to a square. For example, each of the third electrodes E3 may have a square shape when viewed in plan view. For example, the distance from the active pattern ACT to the corresponding third electrode E3 may be smaller than the distance from the active pattern ACT to the corresponding second electrode E2.

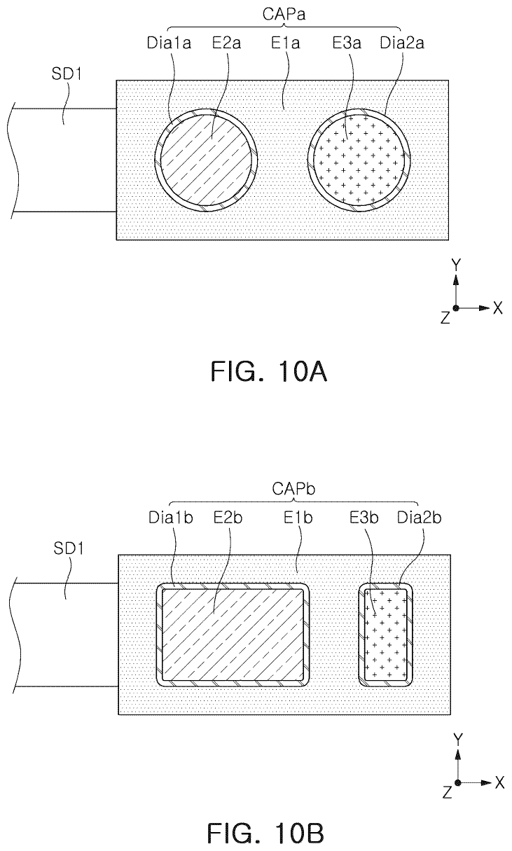

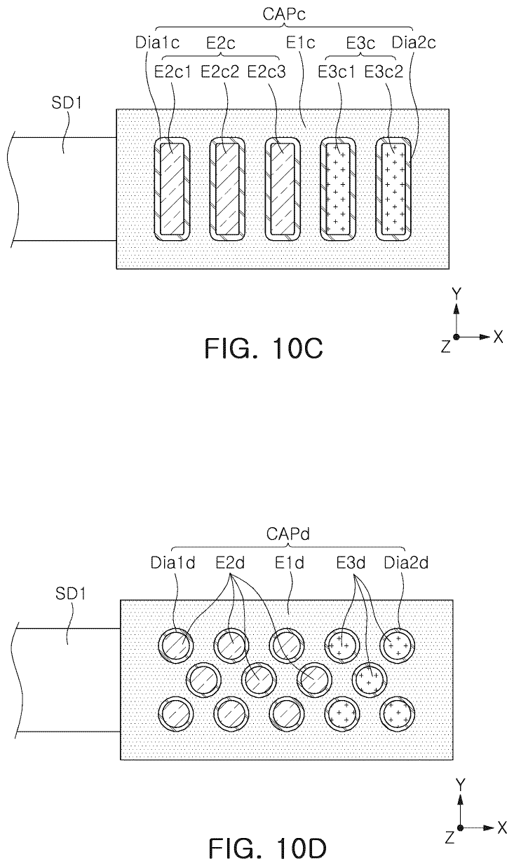

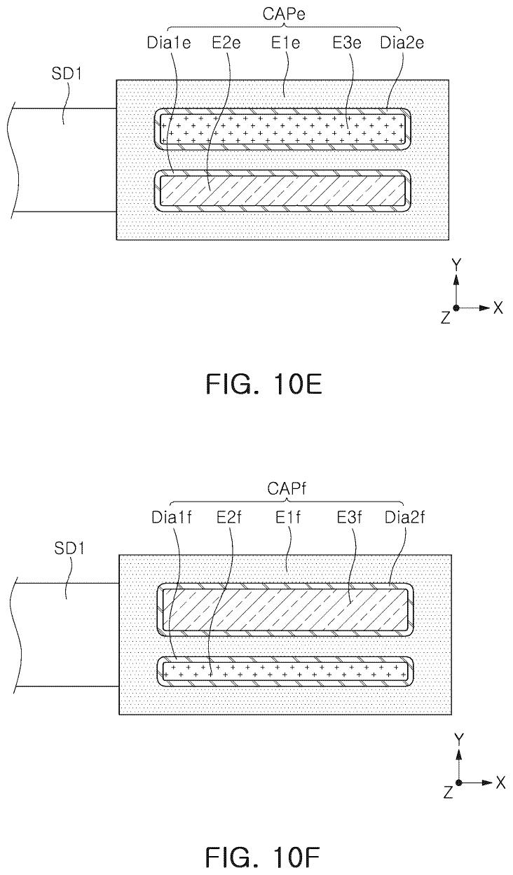

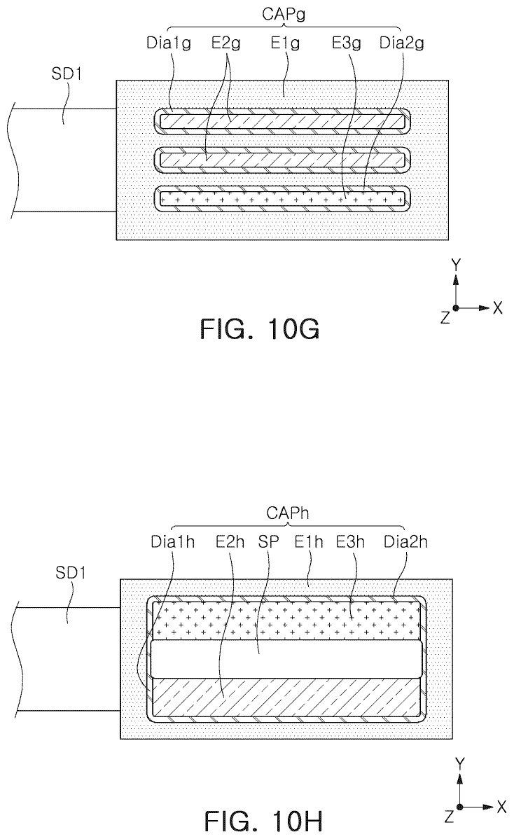

FIGS. 10A to 10I are plan views illustrating various examples of a planar shape of the capacitor structure C1 (see FIG. 2A) described above. Hereinafter, elements referred to by symbols different from symbols described above, but referred to by the same term, may differ only in planar shape, and may play the same role as each other. In a modified example, referring to FIG. 10A, the capacitor structure C1 (see FIG. 2A) may be modified into a capacitor structure CAPa as in FIG. 10A. For example, the first electrode E1 (see FIG. 2A) in FIG. 2A may be modified into a first electrode E1a having a width larger than the first source/drain region SD1, and the second electrode E2 (see FIG. 2A) in FIG. 2A may be modified into a second electrode E2a disposed adjacently to the first source/drain region SD1, the third electrode E3 (see FIG. 2A) in FIG. 2A may be modified into a third electrode E3a disposed in a position farther away from the first source/drain region SD1 than the second electrode E2a, the first dielectric layer Dia1 in FIG. 2A may be modified into a first dielectric layer Dia1a disposed between the first electrode E1a and the second electrode E2a, and the second dielectric layer Dia2 in FIG. 2A may be modified into a second dielectric layer Dia2a disposed between the first electrode E1a and the third electrode E3a. Each of the second electrode E2a and the third electrode E3a may be circular or substantially circular, or have a shape similar to a circle.

Each of the active patterns ACT (see FIGS. 2A and 2B) including the first source/drain region SD1 may have a bar shape extending in the first horizontal direction (X-direction), and each of the active patterns ACT (see FIGS. 2A and 2B) may have a first width in the second horizontal direction (Y-direction), and the first electrode E1a may have a second width larger than the first width in the second horizontal direction (Y-direction). The second electrode E2a and the third electrode E3a may be sequentially arranged in the first horizontal direction (X-direction).

In a modified example, referring to FIG. 10B, the capacitor structure C1 (see FIG. 2A) may be modified into a capacitor structure CAPb as in FIG. 10B. For example, the first electrode E1 (see FIG. 2A) in FIG. 2A may be modified into a first electrode E1b having a width larger than the first source/drain region SD1, the second electrode E2 (see FIG. 2A) in FIG. 2A may be modified into a second electrode E2b with an increased planar area, the third electrode E3 (see FIG. 2A) in FIG. 2A may be modified into a third electrode E3b with a reduced planar area, the first dielectric layer Dia1 in FIG. 2A may be modified into a first dielectric layer Dia1b disposed between the first electrode E1b and the second electrode E2b, and the second dielectric layer Dia2 in FIG. 2A may be modified into a second dielectric layer Dia2b disposed between the first electrode E1b and the third electrode E3b.

At the same level as the active pattern ACT (see FIGS. 2A and 2B), when viewed from top view (e.g., plan view), a planar area of the second electrode E2b may be different from a planar area of the third electrode E3b. For example, at the same level as the active pattern ACT (see FIGS. 2A and 2B), when viewed from top view, the planar area of the second electrode E2b may be larger than the planar area of the third electrode E3b. For example, the planar area of the third electrode E3b may be about 0.1 to 0.8 times the planar area of the second electrode E2b. The planar area of the third electrode E3b may be about 0.3 to 0.6 times the planar area of the second electrode E2b.

The second electrode E2b may be disposed between the third electrode E3b and the first source/drain region SD1, but the inventive concept is not limited thereto. For example, the third electrode E3b may be modified to be disposed between the second electrode E2b and the first source/drain region SD1.

In a modified example, referring to FIG. 10C, the capacitor structure CAPb (see FIG. 10B) in FIG. 10B may be modified into a capacitor structure CAPc as in FIG. 10C. For example, the first electrode E1 (see FIG. 2A) in FIG. 2A may be modified into a first electrode E1c having a width larger than the first source/drain region SD1, and the second electrode E2b (see FIG. 10B) in FIG. 10B may be modified into a second electrode E2c including a plurality of second electrode patterns E2c1, E2c2 and E2c3 spaced apart from each other. The third electrode E3b (see FIG. 10B) in FIG. 10C may be modified into a third electrode E3c including a plurality of third electrode patterns E3cl and E3c2 spaced apart from each other. The first dielectric layer Dia1b in FIG. 10B may be modified into a first dielectric layer Dia1c disposed between the first electrode E1c and the plurality of second electrode patterns E2c1, E2c2 and E2c3, and the second dielectric layer Dia2b in FIG. 10B may be modified into a second dielectric layer Dia2c disposed between the first electrode E1c and the plurality of third electrode patterns E3cl and E3c2.

Each of the plurality of second electrode patterns E2c1, E2c2 and E2c3 and the plurality of third electrode patterns E3cl and E3c2 may be a bar shape extending in the second horizontal direction (Y-direction).

The plurality of second electrode patterns E2c1, E2c2 and E2c3 and the plurality of third electrode patterns E3cl and E3c2 may have the same size as each other.

The number of the plurality of second electrode patterns E2c1, E2c2 and E2c3 may be greater than the number of the plurality of third electrode patterns E3cl and E3c2.

In a modified example, referring to FIG. 10D, the capacitor structure CAPb (see FIG. 10B) in FIG. 10B may be modified into a capacitor structure CAPd as in FIG. 10D. For example, the first electrode E1 (see FIG. 2A) in FIG. 2A may be modified into a first electrode E1d having a width larger than the first source/drain region SD1. The second electrode E2b (FIG. 10B) in FIG. 10B may be modified into a second electrode E2d including a plurality of second electrode patterns spaced apart from each other. The third electrode E3b (see FIG. 10B) in FIG. 10C may be modified into a third electrode E3d including a plurality of third electrode patterns spaced apart from each other. The first dielectric layer Dia1b in FIG. 10B may be modified into a first dielectric layer Dia1d disposed between the first electrode E1d and a plurality of second electrode patterns of the second electrode E2d, and the second dielectric layer Dia2b in FIG. 10B may be modified into a second dielectric layer Dia2d disposed between the first electrode E1d and the plurality of third electrode patterns of the third electrode E3d.

The plurality of second electrode patterns of the second electrode E2d and the plurality of third electrode patterns of the third electrode E3d may be the same size as each other.

Each of the plurality of second electrode patterns of the second electrode E2d and the plurality of third electrode patterns of the third electrode E3d may be substantially circular or substantially square in shape.

The electrode patterns of the second and third electrodes E2d and E3d may be arranged in the first horizontal direction (X-direction) while crossing in the second horizontal direction (Y-direction).

The number of second electrode patterns of the second electrode E2d may be greater than the number of third electrode patterns of the third electrode E3d.

In a modified example, referring to FIG. 10E, the capacitor structure C1 (see FIG. 2A) may be modified into a capacitor structure CAPe as in FIG. 10E. For example, the first electrode E1 (see FIG. 2A) in FIG. 2A may be modified into a first electrode E1e having a width larger than the first source/drain region SD1, the second electrode E2 (see FIG. 2A) in FIG. 2A may be modified into a bar-shaped second electrode E2e extending in the first horizontal direction (X-direction), the third electrode E3 (see FIG. 2A) in FIG. 2A may be modified into a bar-shaped third electrode E3e extending in the first horizontal direction (X-direction), the first dielectric layer Dia1 in FIG. 2A may be modified into a first dielectric layer Dia1e disposed between the first electrode E1e and the second electrode E2e, and the second dielectric layer Dia2 in FIG. 2A may be modified into a second dielectric layer Dia2e disposed between the first electrode E1e and the third electrode E3e.

The second electrode E2e and the third electrode E3e may be sequentially arranged in the second horizontal direction (Y-direction).

In a modified example, referring to FIG. 10F, the capacitor structure CAPb (see FIG. 10B) may be modified into a capacitor structure CAPf as in FIG. 10F. For example, the first electrode E1 (see FIG. 2A) in FIG. 2A may be modified into a first electrode E1f having a width larger than the first source/drain region SD1, the second electrode E2b (see FIG. 10B) in FIG. 10B may be modified into a bar-shaped second electrode E2f extending in the first horizontal direction (X-direction), and the third electrode E3b (see FIG. 10B) in FIG. 10B may be modified into a bar-shaped third electrode E3f extending in the first horizontal direction (X-direction). The first dielectric layer Dia1b in FIG. 10B may be modified into a first dielectric layer Dia1f disposed between the first electrode E1f and the second electrode E2f, and the second dielectric layer Dia2b in FIG. 10B may be modified into a second dielectric layer Dia2f disposed between the first electrode E1f and the third electrode E3f.

The third electrode E2f and the second electrode E2f may be sequentially arranged in the second horizontal direction (Y-direction). As described in FIG. 10B, a planar area of the third electrode E2f may be larger than a planar area of the second electrode E2f.

In a modified example, referring to FIG. 10G, the capacitor structure CAPe (see FIG. 10E) may be modified into a capacitor structure CAPg as in FIG. 10G. The first electrode E1 (see FIG. 2A) in FIG. 2A may be modified into a first electrode E1g having a width larger than the first source/drain region SD1. The second electrode E2e (see FIG. 10E) in FIG. 10E may be modified into a second electrode E2g including a plurality of second electrode patterns spaced apart from each other. A third electrode E3g having a similar shape as the third electrode E3e (see FIG. 10E) in FIG. 10E may be provided. The first dielectric layer Dia1e in FIG. 10E may be modified into a first dielectric layer Dia1g disposed between the first electrode E1g and a plurality of second electrode patterns of the second electrode E2g, and the second dielectric layer Dia2e in FIG. 10E may be modified into a second dielectric layer Dia2g disposed between the first electrode E1g and the third electrode E3g.

The electrode patterns of the second electrode E2g may be sequentially arranged in the second horizontal direction (Y-direction). The third electrode E3g and the second electrode E2g may be sequentially arranged in the second horizontal direction (Y-direction). Each of the electrode patterns of the second electrode E2g and the third electrode E3g may be in a shape of a line extending in the first horizontal direction (X-direction). The electrode patterns of the second electrode E2g and the third electrode E3g may have substantially the same size.

In a modified example, referring to FIG. 10H, the capacitor structure C1 (See FIG. 2A) may be modified into a capacitor structure CAPh as in FIG. 10H. For example, the first electrode E1 (see FIG. 2A) in FIG. 2A may be modified into a first electrode E1h having a width larger than the first source/drain region SD1, the second electrode E2 (see FIG. 2A) in FIG. 2A may be modified into a bar-shaped second electrode E2h extending in the first horizontal direction (X-direction), the third electrode E3 (see FIG. 2A) in FIG. 2A may be modified into a bar-shaped third electrode E3h extending in the first horizontal direction (X-direction), the first dielectric layer Dia1 in FIG. 2A may be modified into a first dielectric layer Dia1h disposed between the first electrode E1h and the second electrode E2h, and the second dielectric layer Dia2 in FIG. 2A may be modified into a second dielectric layer Dia2h disposed between the first electrode E1h and the third electrode E3h. The first dielectric layer Dia1h and the second dielectric layer Dia2h may contact each other or may be continuously formed of a single material.

The capacitor structure CAPh may further include an insulating separation pattern SP disposed between the second electrode E2h and the third electrode E3h separating the second electrode E2h and the third electrode E3h from each other. The insulating separation pattern SP may be in contact with the second electrode E2h and the third electrode E3h between the second electrode E2h and the third electrode E3h.

In a modified example, referring to FIG. 10I, the first source/drain region described in the example embodiments described in FIGS. 1 to 10H may be modified into a first source/drain region SD1a extending to surround a side surface of the first electrode described in the example embodiments described in FIGS. 1 to 10H. For example, the first source/drain region SD1 in FIG. 10H may be modified into the first source/drain region SD1a extending to surround a side surface of the first electrode E1h of the capacitor structure CAPh (see FIG. 10h) described in FIG. 10H. An entire side surface of the first electrode E1h may be surrounded by the first source/drain region SD1a.

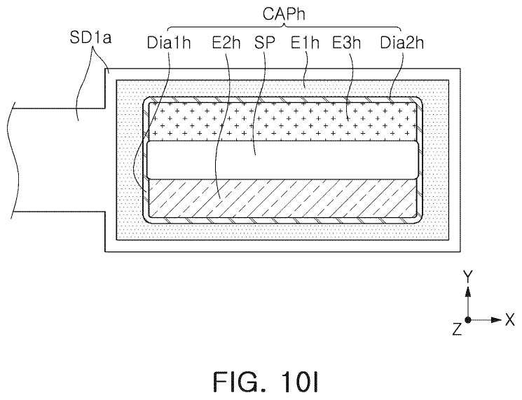

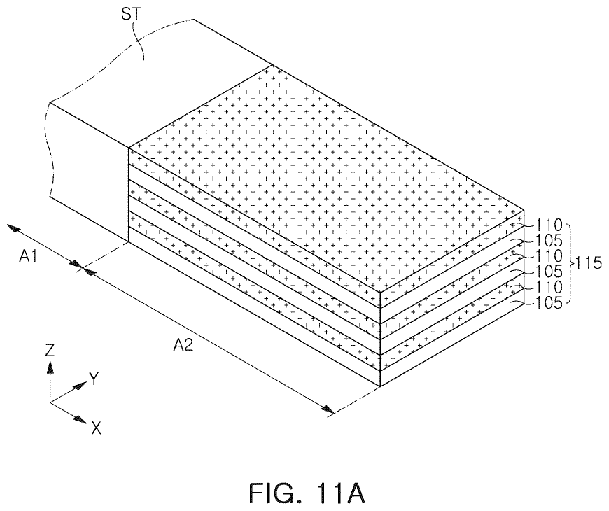

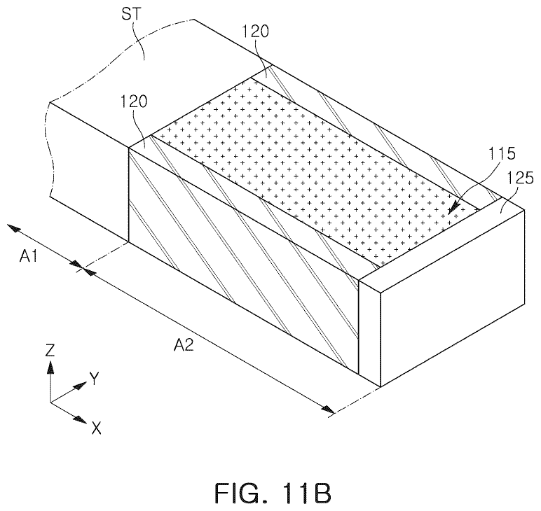

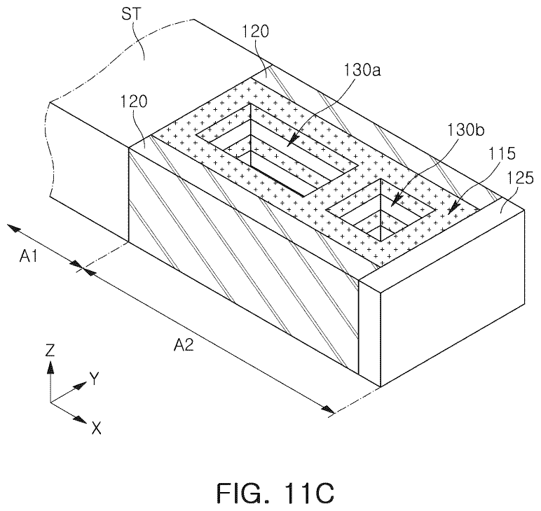

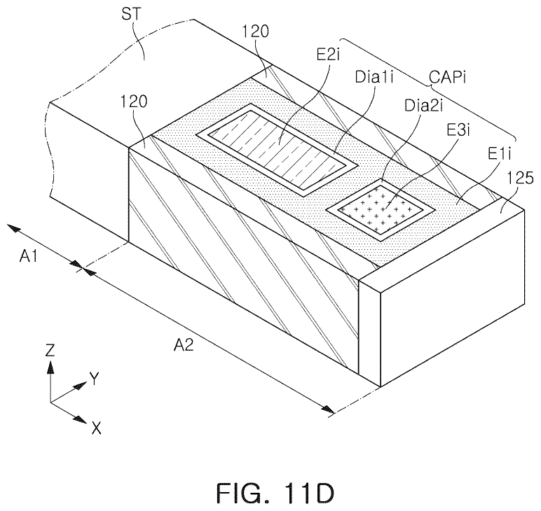

Next, an example of a method of forming a semiconductor device according to an example embodiment of the present disclosure will be described with reference to FIGS. 11A to 11D. FIGS. 11A to 11D are perspective views illustrating a portion of a region in which the capacitor structure is to be formed, to describe a method of forming the capacitor structure in the previously described example embodiments.

Referring to FIG. 11A, a stack structure 115 may be formed on a first region A1 and a second region A2. A semiconductor process may be performed on the stack structure 115 on the first region A1, thus forming a structure ST including the active patterns ACT, the word lines WL, the gate dielectric layers Gox, and the bit lines BL described in the example embodiments of FIGS. 1 to 10I.

The stack structure 115 may include first layers 105 and second layers 110 that are alternately stacked. The first layers 105 may be interlayer insulating layers. The second layers 110 may be formed of the same material as the active patterns ACT. For example, the second layers 110 may be silicon layers. In another example, the second layers 110 of the stack structure 115 on the first region A1 and the second layers 110 of the stack structure 115 on the second region A2 may be formed from layers of different materials. For example, by an ion implantation process, the second layers 110 of the stack structure 115 on the first region A1 may be formed of a semiconductor layer such as a silicon layer, and the second layers 110 of the stack structure 115 on the second region A2 may be formed of an insulating layer such as silicon nitride.

Referring to FIG. 11B, a semiconductor process may be performed on the stack structure 115 on the second region A2, thus forming first insulating patterns 120 defining side surfaces opposite to each other in the second horizontal direction (Y-direction) and a second insulating pattern 125 defining a side surface spaced apart from the first region A1 in the first horizontal direction (X-direction).

In one example, the first insulating patterns 120 and the second insulating pattern 125 may be formed in the same process.

In another example, the first insulating patterns 120 and the second insulating pattern 125 may be formed in different processes.

Referring to FIG. 11C, a plurality of openings 130a and 130b spaced apart from each other may be formed by penetrating through the stack structure 115 on the second region A2. The plurality of openings 130a and 130b may include a first opening 130a and a second opening 130b.

The planar shapes of the plurality of openings 130a and 130b may be substantially the same as the planar shapes of the elements referred to as the “second electrode” and “third electrode” described above. According to an example embodiment, the first opening 130a may have a larger planar area than the second opening 130b. Referring to FIG. 11D, the second layers 110 (see FIG. 11A) exposed by the first and second openings 130a and 130b may be selectively removed to expose the active patterns ACT (see FIGS. 2A and 2B) of the structure ST. Next, impurities may be injected into the active patterns ACT (see FIGS. 2A and 2B) of the structure ST, thus forming first source/drain regions SD1 as described above. Then, first electrodes E1i may be formed in spaces from which the second layers 110 (see FIG. 11A) are removed. dielectric layers Dia1i and Dia2i may be formed on sidewalls of the first and second openings 130a and 130b, and conductive material layers D2i and D3i filling the first and second openings 130a and 130b may be formed.

The dielectric layers Dia1i and Dia2i may cover side surfaces of the first electrodes E1i exposed by the first and second openings 130a and 130b. The dielectric layers Dia1i and Dia2i may include a first dielectric layer Dia1i in the first opening 130a and a second dielectric layer Dia2i in the second opening 130b. The conductive material layers D2i and D3i may include a second electrode D2i in the first opening 130a and a third electrode D3i in the second opening 130b. Accordingly, a capacitor structure CAPi including the first to third electrodes E1i, E2i and E3i and the first and second dielectric layers Dia1i and Dia2i may be formed.

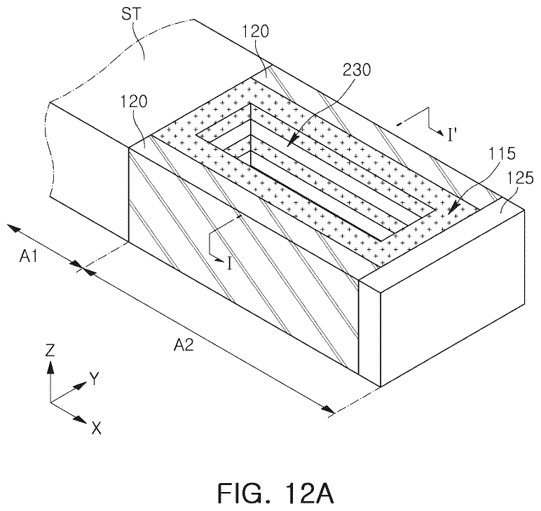

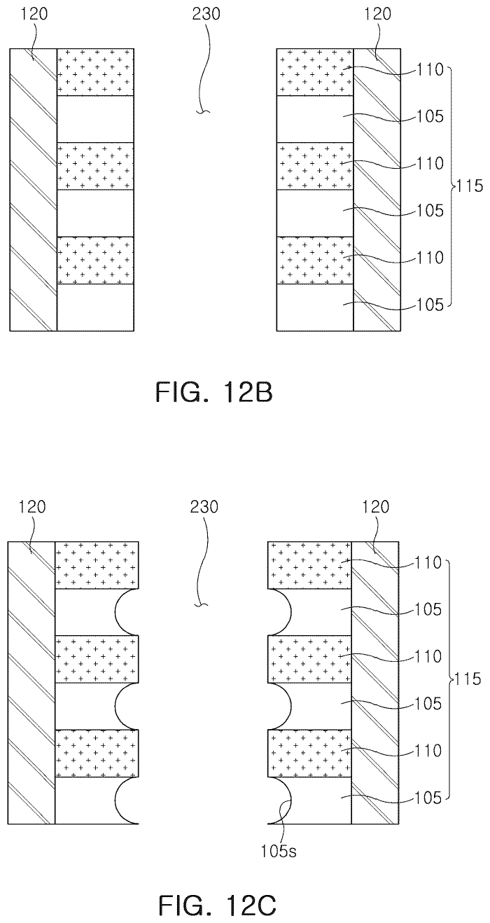

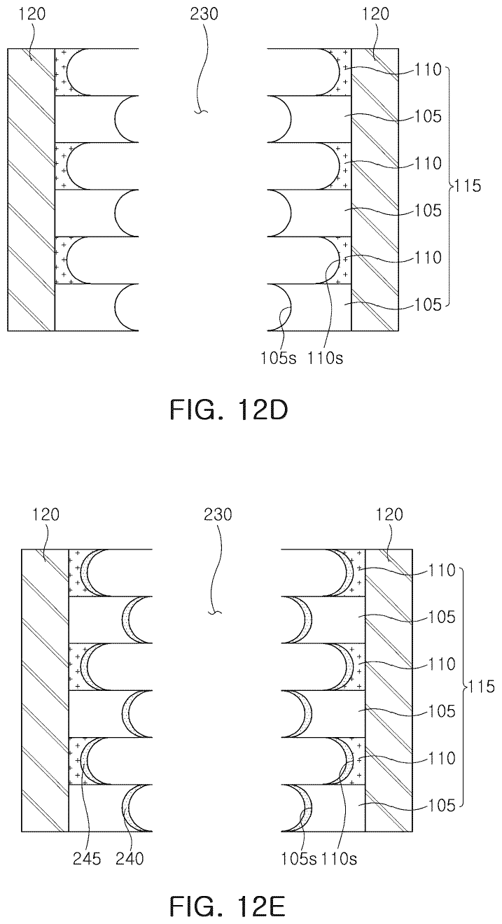

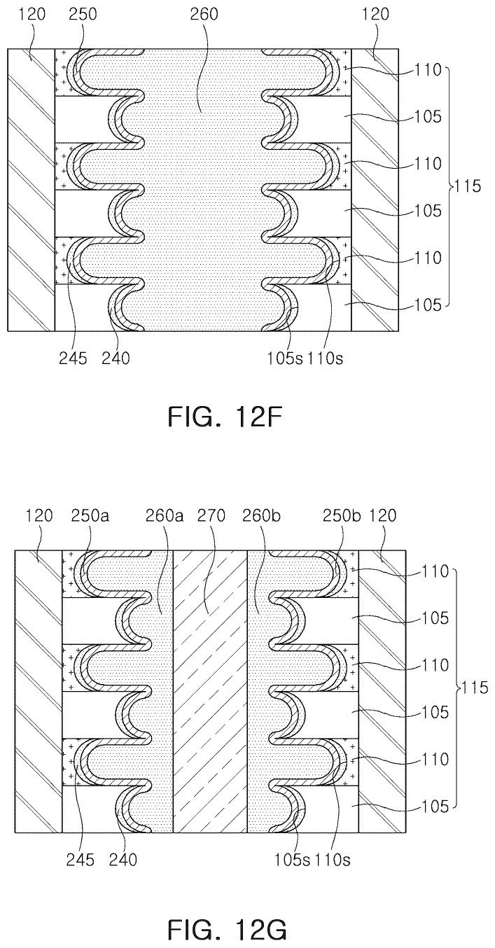

Next, an example of a method of forming a semiconductor device according to an example embodiment of the present disclosure will be described with reference to FIGS. 12A to 12G. FIGS. 12A to 12G are views illustrating a portion of a region in which the capacitor structure is to be formed, to describe the method of forming the capacitor structure in the previously described example embodiments. FIG. 12A is a perspective view illustrating a partial region in which the capacitor structure is to be formed, and FIGS. 12B to 12G are cross-sectional views illustrating a region taken along line I-I′ of FIG. 12A.

Referring to FIGS. 12A and 12B, as described in FIG. 11A, the stack structure 115 may be formed on the first region A1 and the second region A2, and a semiconductor process may be performed on the stack structure 115 on the first region A1, thus forming the structure ST. As described in FIG. 11B, a semiconductor process may be performed on the stack structure 115 on the second region A2, thus forming the first insulating patterns 120 and the second insulating pattern 125. An opening 230 penetrating through the stack structure 115 may be formed on the second region A2. Side surfaces of the first layers 105 and the second layers 110 of the stack structure 115 may be exposed through the opening 230.

Referring to FIGS. 12C and 12D, the first layers 105 exposed by the opening 230 may be isotropically etched to form first recessed regions 105s recessed at a first depth. The second layers 110 exposed by the opening 230 may be isotropically etched so that second recessed regions 110s recessed at a second depth deeper than the first depth may be formed.

In an example embodiment, when the second layers 110 are formed of a semiconductor material, the second recessed regions 110s may be formed, and then, the second layers 110 may remain. By injecting impurities into the second layers 110 and the active patterns ACT (see FIGS. 2A and 2B) of the structure ST, a first source/drain region SD1a (see FIG. 10I) may be formed as described in FIG. 10I.

In another example embodiment, when the second layers 110 are formed of an insulating material such as silicon nitride, the second layers 110 may be removed to expose the first and second insulating patterns 120 and 125 and the active patterns ACT (see FIGS. 2A and 2B) of the structure ST, thus forming the second recessed regions 110s. Next, impurities may be injected into the active patterns ACT (see FIGS. 2A and 2B) of the structure ST, thus forming the first source/drain region SD1 (see FIG. 10h) as illustrated in FIG. 10H.

Hereinafter, a case in which the second layers 110 remain will be described, but the inventive concept is not limited thereto. For example, even when the second layers 110 are removed, the same process may be performed later.

Referring to FIG. 12E, conductive patterns 240 and 245 may be formed on side surfaces of the first recessed regions 105s and side surfaces of the second recessed regions 110s. Because the side surfaces of the first recessed regions 105s and the side surfaces of the second recessed regions 110s have curved surfaces, when a conductive material layer may be deposited thereon and the conductive material layer may then be etch-backed, the conductive material layer remains on the side surfaces of the first recessed regions 105s and the side surfaces of the second recessed regions 110s, thereby forming the conductive patterns 240 and 245.

The conductive patterns 240 and 245 may include dummy conductive patterns 240 formed on side surfaces of the first recessed regions 105s, and first electrodes 245 formed on side surfaces of the second recessed regions 110s. The first electrodes 245 may be the first electrodes E1h described in FIGS. 10H and 10I.

Referring to FIG. 12F, a dielectric layer 250 covering the conductive patterns 240 and 245 may be formed, and a conductive material layer 260 filling the first and second recessed regions 105s and 110s and filling the opening 230 (see FIG. 12E) may be formed on the dielectric layer 250.

Referring to FIG. 12G, an insulating separation pattern 270 penetrating through the conductive material layer 260 may be formed. The conductive material layer 260 may be formed of a second electrode 260a and a third electrode 260b spaced apart from each other by the insulating separation pattern 270. The dielectric layer 250 may include a first dielectric layer 250a remaining between the second electrode 260a and the first electrodes 245 and between the second electrode 260a and the dummy conductive patterns 240, and a second dielectric layer 250b remaining between the third electrode 260b and the first electrodes 245, and between the third electrode 260b and the dummy conductive patterns 240.

The second electrode 260a may be the second electrode E2h described in FIGS. 10H and 10I, the third electrode 260b may be the third electrode E3h described in FIGS. 10H and 10I, and the insulating separation pattern 270 may be the insulating separation pattern SP described in FIGS. 10H and 10I. A semiconductor device including the capacitor structure CAPh described in FIGS. 10H and 10I may include the first layers 105 as in FIG. 12G, and the dummy conductive patterns 240.

Although example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are exemplary and not limited in all respects.

What is claimed is:

1. A semiconductor device comprising:
active patterns stacked and spaced apart from each other in a vertical direction; and
a capacitor connected to the active patterns,
wherein the capacitor includes:
first electrodes respectively connected to the active patterns and stacked and spaced apart from each other in the vertical direction;
a second electrode penetrating through the first electrodes and extending in the vertical direction;
a third electrode penetrating through the first electrodes and extending in the vertical direction, and spaced apart from the second electrode;
first dielectric layers, each first dielectric layer being between a respective first electrode and the second electrode; and
second dielectric layers, each second dielectric layer being between a respective first electrode and the third electrode.

2. The semiconductor device of claim 1, wherein each of the second electrode and the third electrode has a lower surface at a lower level than a lowermost active pattern among the active patterns, and an upper surface at a higher level than an uppermost active pattern among the active patterns.

3. The semiconductor device of claim 1, wherein at the same height level as one first electrode of the first electrodes, a planar area in plan view of the second electrode is different from a planar area in plan view of the third electrode.

4. The semiconductor device of claim 1, wherein the second electrode includes a plurality of second electrode patterns penetrating through the first electrodes in the vertical direction and spaced apart from each other.

5. The semiconductor device of claim 4, wherein the third electrode includes a plurality of third electrode patterns penetrating through the first electrodes in the vertical direction and spaced apart from each other.

6. The semiconductor device of claim 5, wherein the number of the plurality of second electrode patterns is greater than the number of the plurality of third electrode patterns.

7. The semiconductor device of claim 1, wherein each of the second electrode and the third electrode has a bar shape extending in a horizontal direction perpendicular to the vertical direction.

8. The semiconductor device of claim 1, wherein each of the active patterns has a bar shape extending in a first horizontal direction,
wherein each of the active patterns has a first width in a second horizontal direction perpendicular to the first horizontal direction, and
wherein each of the first electrodes has a second width greater than the first width in the second horizontal direction.

9. The semiconductor device of claim 1, wherein each of the active patterns has a bar shape extending in a first horizontal direction, and
wherein the second electrode and the third electrode are sequentially arranged in the first horizontal direction.

10. The semiconductor device of claim 1, wherein each of the active patterns has a bar shape extending in a first horizontal direction, and
wherein the second electrode and the third electrode are sequentially arranged in a second horizontal direction perpendicular to the first horizontal direction.

11. The semiconductor device of claim 1, wherein each of the active patterns has a bar shape extending in a first horizontal direction,
wherein each of the active patterns includes a first source/drain region, a second source/drain region, and a channel region between the first source/drain region and the second source/drain region, and
wherein the first electrodes are connected to the first source/drain regions of the active patterns.

12. The semiconductor device of claim 11, further comprising:
a bit line connected to the second source/drain region of each of the active patterns, the bit line extending in the vertical direction; and
a word line vertically overlapping the channel region of each of the active patterns, the word line extending in a second horizontal direction perpendicular to the first horizontal direction.

13. The semiconductor device of claim 11, further comprising:
bit lines, each bit line being connected to the second source/drain region of a corresponding active pattern, and each bit line extending in a second horizontal direction perpendicular to the first horizontal direction; and
a word line including a vertical portion extending in the vertical direction, and protruding portions extending from the vertical portion,
wherein each protruding portion vertically overlaps the channel region of a corresponding active pattern.

14. A semiconductor device comprising:
a peripheral circuit region including a peripheral circuit; and
a memory region on the peripheral circuit region and including cell blocks,
wherein each of the cell blocks includes cell transistors and a data storage structure connected to first source/drain regions of the cell transistors,
wherein the data storage structure of each of the cell blocks includes:
first electrodes respectively connected to the first source/drain regions of the cell transistors, the first electrodes being stacked and spaced apart from each other in a vertical direction;
a second electrode having a side surface facing the first electrodes; and
a third electrode having a side surface facing the first electrodes and spaced apart from the second electrode, and
wherein the peripheral circuit includes:
a fixed voltage supply circuit configured to apply a fixed voltage to the second electrode;
a write circuit configured to perform a write operation for storing “1” or “0” data in a unit memory cell of the cell blocks; and
a variable voltage supply circuit configured to, during the write operation for storing data “1” in the unit memory cell, apply a positive voltage to the third electrode, and to, during the write operation for storing “0” data in the unit memory cell, apply a negative voltage to the third electrode.

15. The semiconductor device of claim 14, further comprising:
a first routing interconnection structure electrically connecting the second electrode to the fixed voltage supply circuit; and
a second routing interconnection structure electrically connecting the third electrode to the variable voltage supply circuit.

16. The semiconductor device of claim 15, wherein the first routing interconnection structure is connected to a lower surface of the second electrode, and
wherein the second routing interconnection structure is connected to an upper surface of the third electrode.

17. The semiconductor device of claim 15, wherein the first routing interconnection structure is connected to an upper surface of the second electrode, and
wherein the second routing interconnection structure is connected to a lower surface of the third electrode.

18. The semiconductor device of claim 15, wherein the peripheral circuit further includes a read circuit and voltage control circuits, the read circuit being configured to read data stored in the unit memory cell,
wherein the cell blocks include a first cell block and a second cell block,
wherein the voltage control circuits include a first voltage control circuit configured to apply a first voltage to the third electrode of the first cell block and a second voltage control circuit configured to apply a second voltage to the third electrode of the second cell block,
wherein each of the first voltage control circuit and the second voltage control circuit includes unit voltage control cells connected in parallel,
wherein each of the unit voltage control cells includes a capacitor, a fuse, and a transistor connected in series,
wherein the unit voltage control cells of the first voltage control circuit include ‘m’ unit voltage control cells in an off state,
wherein the unit voltage control cells of the second voltage control circuit include ‘n’ unit voltage control cells in an off state, and
wherein ‘n’ and ‘m’ are different natural numbers.

19. A semiconductor device comprising:
active patterns stacked and spaced apart from each other in a vertical direction; and
a data storage structure connected to the active patterns,
wherein the data storage structure includes:
first electrodes respectively connected to the active patterns, the first electrodes being stacked and spaced apart from each other in the vertical direction;
a second electrode having a side surface facing the first electrodes;
a third electrode having a side surface facing the first electrodes and spaced apart from the second electrode;
first dielectric layers between respective first electrodes and the second electrode; and
second dielectric layers between respective first electrodes and the third electrode.

20. The semiconductor device of claim 19, further comprising:
a first routing interconnection structure connected to an upper surface of the second electrode; and
a second routing interconnection structure connected to a lower surface of the third electrode.
